(19) United States
(12) Patent Application Publication
(10) Pub. No.: US 2012/0214297 A1
(43) Pub. Date: Aug. 23, 2012

(54) METHOD OF FABRICATING SEMICONDUCTOR DEVICE INCLUDING BURIED CHANNEL ARRAY TRANSISTOR

(76) Inventors: Kwan-Sik Cho, Hwaseong-si (KR); Deok-Sung Hwang, Suwon-si (KR); Kye-Hee Yeom, Suwon-si (KR)

(21) Appl. No.: 13/351,439

(22) Filed: Jan. 17, 2012

(30) Foreign Application Priority Data
Feb. 22, 2011 (KR) 10-2011-0015630

(51) Int. Cl. H01L 21/28

(52) U.S. Cl. 438/586; 438/589; 257/E21.19

(57) ABSTRACT

A method of fabricating a semiconductor device includes partially removing an active region and an isolation region to form a gate buried trench, forming a gate insulating layer on an inner wall of the gate buried trench, forming a gate conductive pattern on the gate insulating layer to fill the gate buried trench, and a height of an uppermost surface of the gate conductive pattern is lower than a height of an uppermost surface of the substrate. The method also includes forming an interlayer insulating layer on the substrate and on the gate conductive pattern, the interlayer insulating layer includes an upper insulating region and a lower insulating region, the lower insulating region fills the gate buried trench, the upper insulating region is formed over the substrate, and forming a bit contact plug connected to the active region through the interlayer.

### CROSS-REFERENCE TO RELATED APPLICATION

This application claims priority under 35 U.S.C. §119 to Korean Patent Application No. 10-2011-0015630 filed on Feb. 22, 2011, in the Korean Intellectual Property Office, and entitled “Method of Fabricating Semiconductor Device Including Buried Channel Array Transistor,” the disclosure of which is hereby incorporated by reference in its entirety.

### BACKGROUND

As the design of semiconductor devices has evolved, the structure has become more elaborate. Accordingly, processes of fabricating the semiconductor devices have become more complicated.

### SUMMARY

Embodiments may be realized by providing a method of fabricating a semiconductor device that includes forming an isolation region in a substrate to define an active region, partially removing the active region and the isolation region to form a gate buried trench, forming a gate insulating layer on an inner wall of the gate buried trench, forming a gate conductive pattern on the gate insulating layer to fill the gate buried trench, a height of an uppermost surface of the gate conductive pattern is lower than a height of an uppermost surface of the substrate, forming an interlayer insulating layer on the substrate and on the gate conductive pattern, the interlayer insulating layer includes an upper insulating region and a lower insulating region, the lower insulating region fills the gate buried trench, the upper insulating region is formed over the substrate, forming a bit contact plug connected to the active region through the interlayer insulating layer.

The interlayer insulating layer may include at least one of silicon carbonic hydroxide, tetraethyl orthosilicate, undoped silicate glass, and boron phosphorus silicate glass.

The method may include forming an anti oxidation layer on the gate conductive pattern before forming the interlayer insulating layer. Forming the anti-oxidation layer may includes depositing the anti-oxidation layer on the substrate, the gate insulating layer, and the gate conductive pattern, the anti-oxidation layer includes a silicon nitride layer or a silicon oxynitride layer, and removing portions of the anti-oxidation layer from the substrate. The anti-oxidation layer may include a silicon nitride layer or a silicon oxynitride layer.

Forming the gate buried trench may includes forming a trench mask on the substrate to partially expose the active region and the isolation region, and using the trench mask as an etch mask while partially removing the exposed active region and isolation region. Forming the trench mask may include forming a pad oxide pattern and a mask pattern using a photolithography process to partially expose the active region and the isolation region. The method may include removing the mask pattern before forming the interlayer insulating layer.

Forming the bit contact plug may includes forming a plug mask on the interlayer insulating layer, partially removing the interlayer insulating layer using the plug mask as an etch mask to form a bit contact hole partially exposing the active region, and forming the bit contact plug in the bit contact hole.

The method may include sequentially forming a bit conductive layer and a hard mask layer on the bit contact plug, and the bit conductive layer may include a lower metal silicide layer, a barrier layer, an upper metal silicide layer, and an electrode layer. The method may include partially removing the hard mask layer to form a hard mask pattern. The method may include performing a patterning process using the hard mask pattern as an etch mask to form a bit contact plug and a bit conductive pattern on the active region, and the bit conductive pattern may include a bit lower metal silicide pattern, a bit barrier pattern, a bit upper metal silicide pattern, and a bit electrode pattern.

The substrate may include a cell area and a peripheral area. The lower metal silicide layer, the barrier layer, the upper metal silicide layer, and the electrode layer may be formed in both the cell area and the peripheral area. The bit lower metal silicide pattern, the bit barrier pattern, the bit upper metal silicide pattern, and the bit electrode pattern of the cell area may be formed at substantially the same levels as the bit lower metal silicide pattern, the bit barrier pattern, the bit upper metal silicide pattern, and the bit electrode pattern of the peripheral area.

Embodiments may also be realized by providing a method of fabricating a semiconductor device that includes forming an isolation region in a substrate to define an active region, forming a trench mask on the substrate to partially expose the active region and the isolation region, partially removing the active region and the isolation region using the trench mask as an etch mask to form a gate buried trench, forming a gate insulating layer on an inner wall of the gate buried trench, forming a gate conductive pattern on the gate insulating layer to partially fill the gate buried trench, forming an anti-oxidation layer on the gate conductive pattern, forming a capping insulating layer on the anti-oxidation layer; and forming an interlayer insulating layer on the substrate.

The capping insulating layer and the interlayer insulating layer may be formed of a same material, and the capping insulating layer and the interlayer insulating layer may include a silicon oxide layer or a silicon oxynitride layer. Forming the anti oxidation layer may include forming a silicon nitride layer on the gate conductive pattern, the gate insulating layer, and the trench mask. Forming the capping insulating layer may include forming a capping insulating material on the trench mask to fill the gate buried trench, and removing portions of the capping insulating material so that the capping insulating material remains within the gate buried trench. During the removal of portions of the capping insulating material, portions of the anti-oxidation layer and the trench mask may be removed from the substrate.

Embodiments may also be realized by providing a method of fabricating a semiconductor device that includes forming an isolation region in a substrate to define an active region, partially removing the active region and the isolation region to form a gate buried trench at a boundary between the active region and the isolation region, forming a gate insulating layer on an inner wall of the gate buried trench, forming a gate conductive pattern on the gate insulating layer to partially fill the gate buried trench, forming an anti-oxidation layer on the gate conductive pattern, the anti oxidation layer includes a silicon nitride layer or a silicon oxynitride layer, forming at least one insulating layer on the anti-oxidation layer, the at least one insulating layer is on the anti-oxidation layer within the gate buried trench and is on an uppermost surface of the substrate, the at least one insulating layer includes a silicon oxide layer, and forming a bit conductive pattern on the at least one insulating layer.

The at least one insulating layer may include a first insulating layer within the gate buried trench and a second insulating layer covering the uppermost surface of the substrate, and both the first insulating layer and the second insulating layer may be formed of a same material. The first insulating layer and the second insulating layer may be formed as one single continuous layer after forming the anti-oxidation layer. The gate conductive pattern may be foamed spaced apart from the at least one insulating layer, and the anti-oxidation layer may be between the gate conductive pattern and the at least one insulating layer. The gate insulating layer, the gate conductive pattern, the anti-oxidation layer, and the at least one insulating layer may be sequentially formed to completely fill the gate buried trench.

### BRIEF DESCRIPTION OF THE DRAWINGS

Features will become apparent to those of ordinary skill in the art by describing in detail exemplary embodiments with reference to the attached drawings, in which:

FIGS. 1A and 1B illustrate schematic layouts of a cell area and a peripheral area of a semiconductor device, according to exemplary embodiments;

FIG. 2 illustrates longitudinal sectional views taken along lines A-A′, B-B′, and C-C′ of the cell area of FIG. 1A and line P-P′ of the peripheral area of FIG. 1B;

FIGS. 3A through 3W illustrate longitudinal sectional views depicting stages in a method of fabricating a semiconductor device according to exemplary embodiments, which are taken along lines A-A′, B-B′, and C-C′ of FIG. 1A and line P-P′ of FIG. 1B;

FIG. 4 illustrates longitudinal sectional views taken along lines A-A′, B-B′, and C-C′ of the cell area of FIG. 1A and line P-P′ of the peripheral area of FIG. 1B;

FIGS. 5A through 5D illustrate longitudinal sectional views depicting various stages in a method of fabricating a semiconductor device according to an exemplary embodiment, which are taken along lines A-A′, B-B′, and C-C′ of FIG. 1A and line P-P′ of FIG. 1B;

FIG. 6 illustrates longitudinal sectional views taken along lines A-A′, B-B′, and C-C′ of the cell area of FIG. 1A and line P-P′ of the peripheral area of FIG. 1B;

FIGS. 7A through 7D illustrate longitudinal sectional views depicting various stages in a method of fabricating a semiconductor device according to an exemplary embodiment, which are taken along lines A-A′, B-B′, and C-C′ of FIG. 1A and line P-P′ of FIG. 1B;

FIGS. 8A through 8C illustrate block diagrams of a semiconductor module, an electronic system, and a memory card, respectively, including various semiconductor packages according to exemplary embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

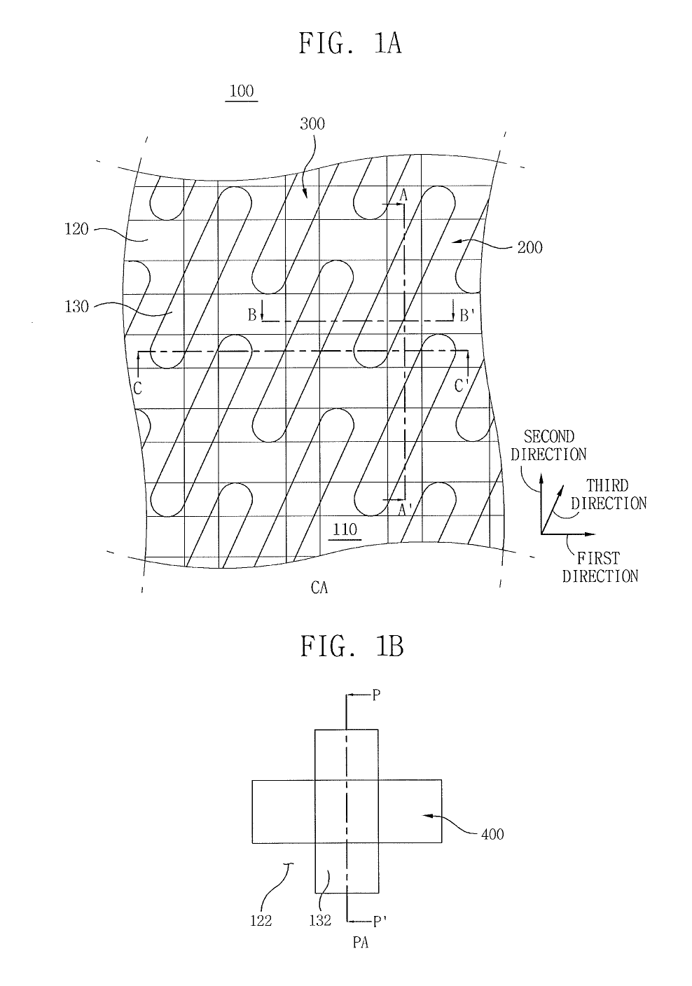

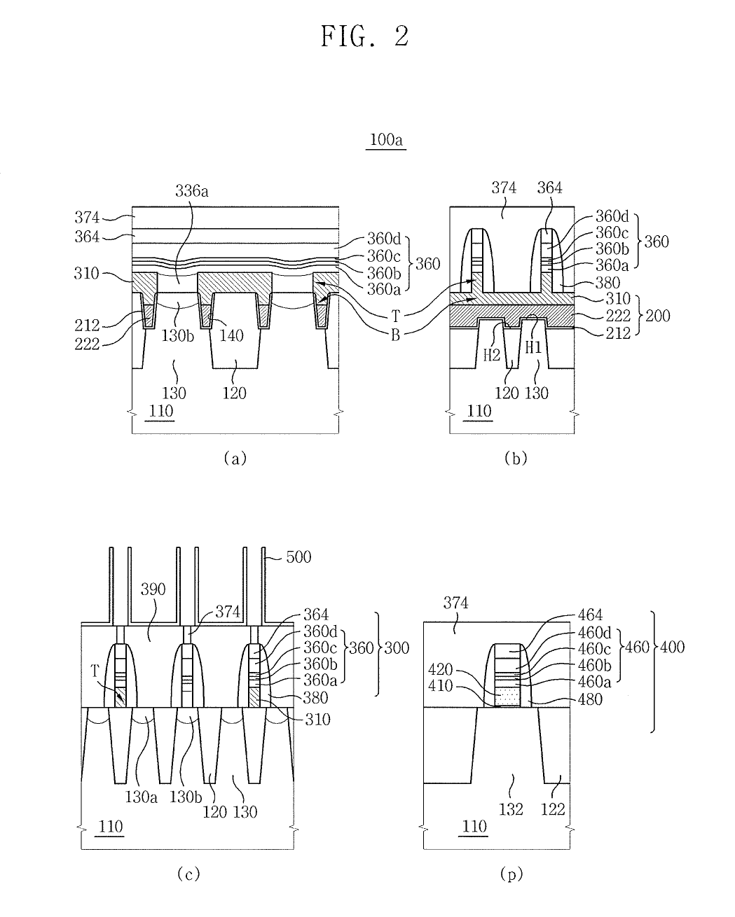

FIGS. 1A and 1B illustrate schematic layouts of a cell area CA and a peripheral area PA of a semiconductor device according to exemplary embodiments. FIG. 2 includes longitudinal section views (a), (b), and (c) taken along lines A-A′, B-B′, and C-C′, respectively, of the cell area CA of FIG. 1A, and longitudinal section view (p) taken along line P-P′ of the peripheral area PA of FIG. 1B.

Referring to FIGS. 1A, 1B, and 2, a semiconductor device 100 (or 100a), according to exemplary embodiments, may include a cell area CA and a peripheral area PA of a substrate 110. The cell area CA may include a plurality of cells, each of which may include, e.g., a single cell gate 200 and a single storage electrode 500. For example, a plurality of cell transistors and a plurality of cell capacitors may be regularly formed, e.g., in a repeating pattern, in the cell area CA. The cell area CA may include, e.g., cell isolation regions 120, cell active regions 130, and cell gates 200, which may be provided within and/or on a surface of the substrate 110, e.g., such that the isolation regions 120, cell active regions 130, and/or cell gates 200 may be provided at a height below a height of an uppermost surface of the substrate 110. The height may be measured with respect to a bottom surface of the substrate 110. The cell area CA may include bit lines 300 and storage electrodes 500, which may be provided on the surface of the substrate 110, e.g., may be provided at a height above the uppermost surface of the substrate 110. Each of the cell gates 200 may be interpreted as a word line WL.

The peripheral area PA may include, e.g., a peripheral gate 400. For example, the peripheral gate 400 may include a complementary-metal-oxide-semiconductor (CMOS) transistor that may constitute a logic circuit. The peripheral area PA may include peripheral isolation regions 122 and peripheral active regions 132, which may be provided under the surface, e.g., under the uppermost surface, of the substrate 110. The peripheral gate 400 may be provided on the surface of the substrate 110, e.g., at a height above the uppermost surface of the substrate 110.

In the cell area CA, the cell active regions 130 may be defined by the cell isolation regions 120. The cell active regions 130 may be repetitively arranged at predetermined intervals, and the cell isolation regions 120 may surround the cell active regions 130. The cell active regions 130 may include cell source regions 130a and cell drain regions 130b, e.g., as illustrated in FIG. 2, which may constitute a portion of the substrate 110. Each cell source region 130a may be adjacent to a cell drain region 130b, e.g., in the first direction. The cell active regions 130 may be diagonally disposed at angles to a first direction and a second direction of the substrate 110. The cell gates 200 may be elongated in the first direction. The bit lines 300 may be elongated in the second direction. The first and second directions may be substantially at right angles to each other. According to an exemplary embodiment, in each of the cell active regions 130, two cell gates 200 may intersect one bit line 300. Portions of one bit line 300 and portions of three cell gates 200 may overlap each cell active region 130.

The cell active regions 130 may be diagonally disposed at predetermined angles with respect to the cell gates 200 and the bit lines 300. A center portion of each cell active region 300 may be directly under one of the bit lines 300. According to an exemplary embodiment, when one cell active region 130 has two unit cells, although one unit cell may have a second-directional length of 4F (here, F refers to a minimum feature size) and a first-directional length of 2F, half of each of left upper and right lower regions of the one unit cell may become a region of an adjacent cell so that the corresponding unit cell may have an area of 6F2. In the above-described area of 6F2 of the cell structure, to minimize the cell area, the cell gate 200 and the bit line 300 may intersect each other at right angles, and the cell active region 130 may be defined as a bar type by the cell isolation region 120 and inclined in a diagonal direction (e.g., third direction) with respect to the cell gate 200 and the bit line 300.

Each of the cell gates 200 may have a recess-type channel disposed in a vertical direction to the substrate 110. For example, each of the cell gates 200 may have a recess-type channel obtained by increasing the length of a gate channel so as to, e.g., suppress a short channel effect (SCE). Each of the cell gates 200 may be provided as a buried type within the substrate 110. In contrast, the peripheral gate 400 of the peripheral area PA may include a planar-type channel, according to an exemplary embodiment. For example, the peripheral gate 400 may be formed on the uppermost surface of the substrate 110.

Each of the cell gates 200 of the cell area CA may include a cell gate insulating layer 212, a cell gate conductive pattern 222, and a first interlayer insulating layer 310. The cell gate insulating layer 212 may be formed, e.g., conformally formed, on an inner wall of the gate buried trench 140 along a profile of the gate buried trench 140. The cell gate conductive pattern 222 may partially fill, e.g., may fill a lower portion of, the gate buried trench 140. The first interlayer insulating layer 310 may fill an upper portion of the gate buried trench 140 to, e.g., protect the cell gate conductive pattern 222. The cell gate insulating layer 212, the cell gate conductive pattern 222, and the first interlayer insulating layer 310 may together fill, e.g., completely fill, the gate buried trench 140. For example, the cell active region 130 disposed under the cell gate conductive pattern 222 may have a top surface level H1 higher than a top surface level H2 of the cell isolation region 120 disposed under the cell gate conductive pattern 222. Thus, the cell gate 200 may function as a transistor having a recess-type channel and the cell active region 130 may protrude toward the cell gate conductive pattern 222.

Each of the bit lines 300 may include a bit conductive pattern 360, a bit hard mask pattern 364, and bit spacers 380. The bit conductive pattern 360 may include, e.g., doped silicon having conductivity, a metal, and/or a metal silicide. The semiconductor device 100a, according to an exemplary embodiment, may include bit contact plugs 336a disposed in respective regions, e.g., the contact plugs 336a may be disposed on the cell active regions 130, respectively. The contact plugs 336a may be spaced apart and may have portions of the first interlayer insulating layer 310 between adjacent contact plugs 336a. The bit conductive patterns 360 may be electrically and/or physically connected to respective ones of the cell drain regions 130b. The bit conductive pattern 360 may be, e.g., bit line electrodes functioning as interconnection lines. The bit hard mask pattern 364 may serve as a bit line capping layer capable of, e.g., protecting the bit conductive pattern 360.

The bit contact plug 336a may include, e.g., doped silicon. Alternatively, the bit contact plug 336a may include, e.g., a metal and/or a metal compound. The bit hard mask pattern 364 may include silicon nitride having, e.g., an insulation characteristic. The bit spacers 380 may include, e.g., silicon oxide and/or silicon nitride.

The bit conductive pattern 360 may include a bit lower metal silicide pattern 360a, a bit barrier pattern 360b, a bit upper metal silicide pattern 360c, and a bit electrode pattern 360d. The bit lower metal silicide pattern 360a and the bit upper metal silicide pattern 360c may include a metal silicide material such as WSi. The bit barrier pattern 360b may include a metal compound such as WN, TiN or TaN. The bit electrode pattern 360d may include a metal or a metal compound.

The peripheral gate 400 may include a peripheral gate insulating layer 410, a first peripheral gate conductive pattern 420, a second peripheral gate conductive pattern 460, a peripheral gate hard mask pattern 464, and peripheral gate spacers 480. The peripheral gate insulating layer 410 may include, e.g., silicon oxide. The second peripheral gate conductive pattern 460 may be formed, e.g., of the same material and/or to the same thickness at the same level or about the same level as the bit conductive pattern 360. The level and/or height of the second peripheral gate conductive pattern 460 and the bit conductive pattern 360 may be measured in the vertical direction with respect to the bottom surface of the substrate 110.

The peripheral gate hard mask pattern 464 may be formed of, e.g., the same material to the same thickness at the same level or about the same level as the bit hard mask pattern 364. The level and/or height of the peripheral gate hard mask pattern 464 and the bit hard mask pattern 364 may be measured in the vertical direction with respect to the bottom surface of the substrate 110. When the bit conductive pattern 360 further includes the bit lower metal silicide pattern 360a, the bit barrier pattern 360b, and the bit upper metal silicide pattern 360c in addition to the bit electrode pattern 360d, the second peripheral gate conductive pattern 460 may further include a peripheral gate lower metal silicide pattern 460a, a peripheral gate barrier pattern 460b, and a bit upper metal silicide pattern 460c in addition to a peripheral gate electrode pattern 460d.

According to an exemplary embodiment, the peripheral gate lower metal silicide pattern 460a may be formed of the same material to the same thickness at the same level or about the same level as the bit lower metal silicide pattern 360a. The peripheral gate barrier pattern 460b may be formed of the same material to the same thickness at the same level or about the same level as the bit barrier pattern 360b. The peripheral gate upper metal silicide pattern 460c may be formed of the same material to the same thickness at the same level or about the same level as the bit upper metal silicide pattern 360c. The peripheral gate electrode pattern 460d may be formed of the same material to the same thickness at the same level or about the same level as the bit electrode pattern 360d. Therefore, the bit conductive pattern 360 and the peripheral gate 400 may each be stacked structures having corresponding heights with respect to, e.g., the bottom surface of the substrate 110.

The semiconductor device 100a, according to an exemplary embodiment, may include storage contact plugs 390 disposed on the substrate 110. The storage contact plugs 390 may be configured to electrically connect the cell source regions 130a and the storage electrodes 500. The storage contact plugs 390 may be below the storage electrodes 500. The storage contact plugs 390 may include, e.g., doped silicon. Adjacent ones of the storage contact plugs 390 may be electrically insulated from each other by a second interlayer insulating layer 374, e.g., the second interlayer insulating layer 374 may remain above the bit conductive pattern 360. The storage contact plugs 390 may be formed through the second interlayer insulating layer 374 between adjacent ones of the bit lines 300.

The semiconductor device 100a, according to an exemplary embodiment, may include the first interlayer insulating layer 310 interposed between the cell gates 200 disposed in the substrate 110 and the bit lines 300 disposed over the substrate 110. For example, the first interlayer insulating layer 310 may be formed under the bit conductive pattern 360, which may not form a contact with the bit contact plug 336a, to electrically insulate the bit conductive pattern 360 from the substrate 110. The first interlayer insulating layer 310 may include an upper insulation region T and a lower insulation region B. The lower insulation region B may refer to a region filling the gate buried trench 140. The lower insulation region B may function as, e.g., a capping insulating layer capable of protecting the cell gate conductive pattern 222. The upper insulation region T may serve as an interlayer insulating layer disposed on the substrate 110 to, e.g., reduce the possibility of and/or prevent a short failure between the substrate 110 and the bit lines 300. The first interlayer insulating layer 310 may include, e.g., a silicon oxide layer. Without intending to be bound by this theory, when the first interlayer insulating layer 310 functioning as the capping insulating layer includes the silicon oxide layer, a parasitic capacitance between the cell gates 200 and the bit lines 300 may be reduced to a greater degree than when a capping insulating layer includes a silicon nitride layer.

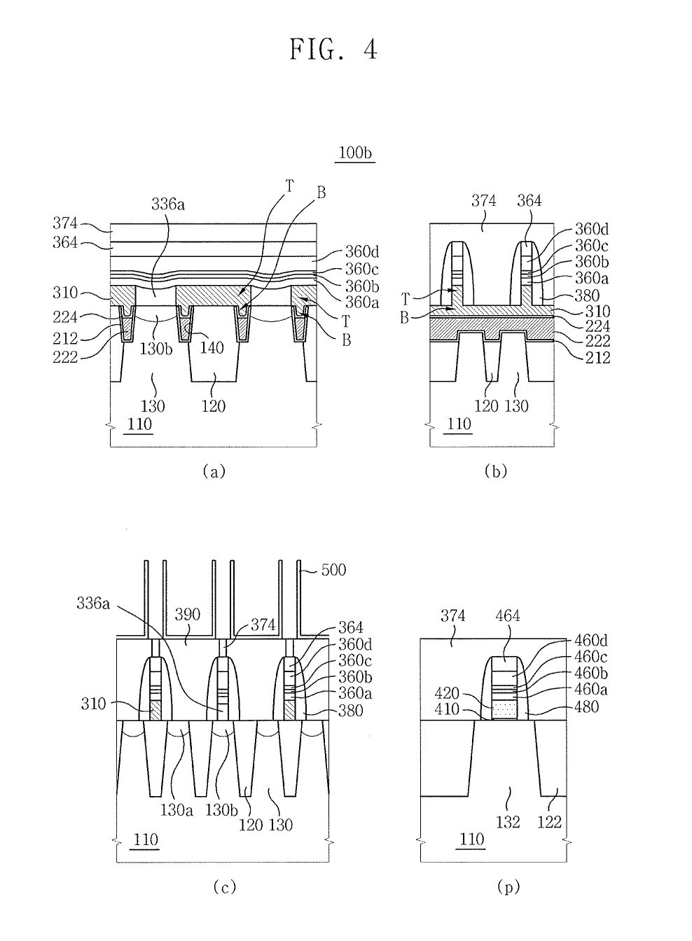

Referring to FIG. 4, a semiconductor device 100b may include an anti-oxidation layer 224 disposed on the cell gate conductive pattern 222. The anti-oxidation layer 224 may be formed on sidewalls of the gate buried trench 140 above the cell gate conductive pattern 222. Without intending to be bound by this theory, when the first interlayer insulating layer 310 is formed directly on the cell gate conductive pattern 222, the cell gate conductive pattern 222 may be oxidized or modified due to, e.g., heterogeneous atoms and/or diffusion of ions. The anti-oxidation layer 224 may reduce the possibility of and/or prevent oxidation or modification of the cell gate conductive pattern 222 due to, e.g., the first interlayer insulating layer 310 being formed on the cell gate conductive pattern 222. The anti-oxidation layer 224 may include, e.g., a silicon nitride layer. According to an exemplary embodiment, if the first interlayer insulating layer 310 includes the upper insulation region T and the lower insulation region B, the lower insulation region B may be disposed within the gate buried trench 140. For example, the lower insulation region B may be on, e.g., directly on, the anti-oxidation layer 224 such that the anti-oxidation layer 224 surrounds the lower insulation region B in the gate buried trench 140.

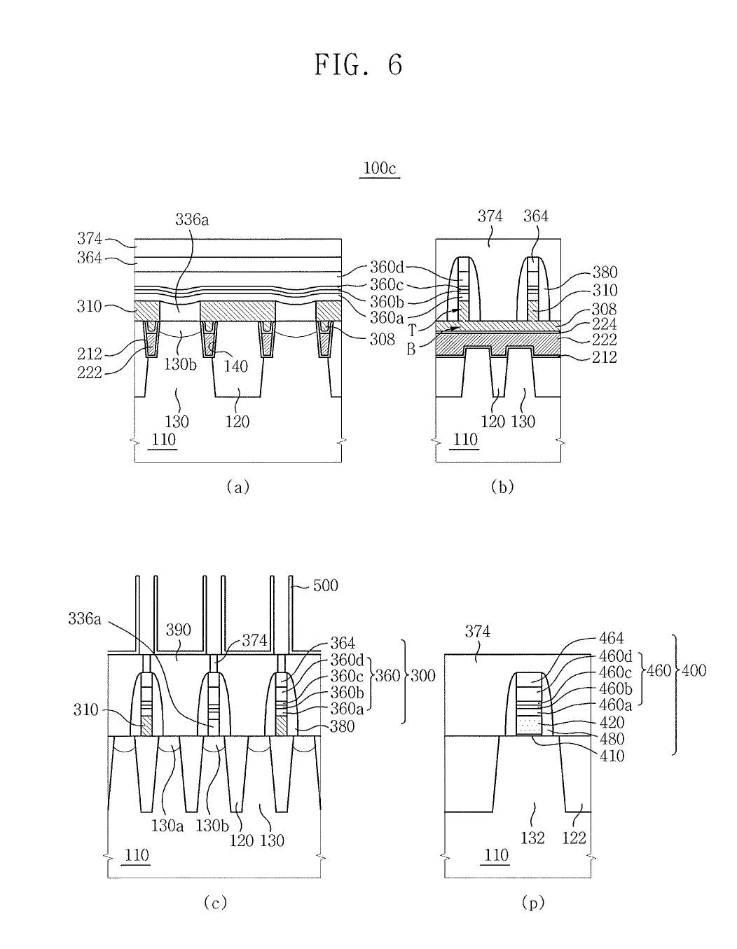

Referring to FIG. 6, a semiconductor device 100c, according to an exemplary embodiment, may include the cell gate conductive pattern 222, the anti-oxidation layer 224, and a capping insulating layer 308 disposed within a gate buried trench 140. The semiconductor device 100c may include a first interlayer insulating layer 310 interposed between the substrate 110 and the bit conductive patterns 360. The capping insulating layer 308 and the first interlayer insulating layer 310 may be formed of the same material. The capping insulating layer 308 and the first interlayer insulating layer 310 may include, e.g., a silicon oxide layer. A silicon oxide layer having, e.g., a low dielectric constant, may be interposed between the bit conductive patterns 360 and cell gate conductive patterns 222, and a parasitic capacitance caused by bit lines may be reduced. In this case, a lower insulation region B and an upper insulation region T may be formed using separate processes and distinguished from each other. The capping insulating layer 308 may correspond to the lower insulation region B, while the first interlayer insulating layer 310 may correspond to the upper insulation region T.

Hereinafter, a method of fabricating a semiconductor device having the above-described construction according to an exemplary embodiment will be described in detail with reference to the appended drawings.

### Method Embodiment 1

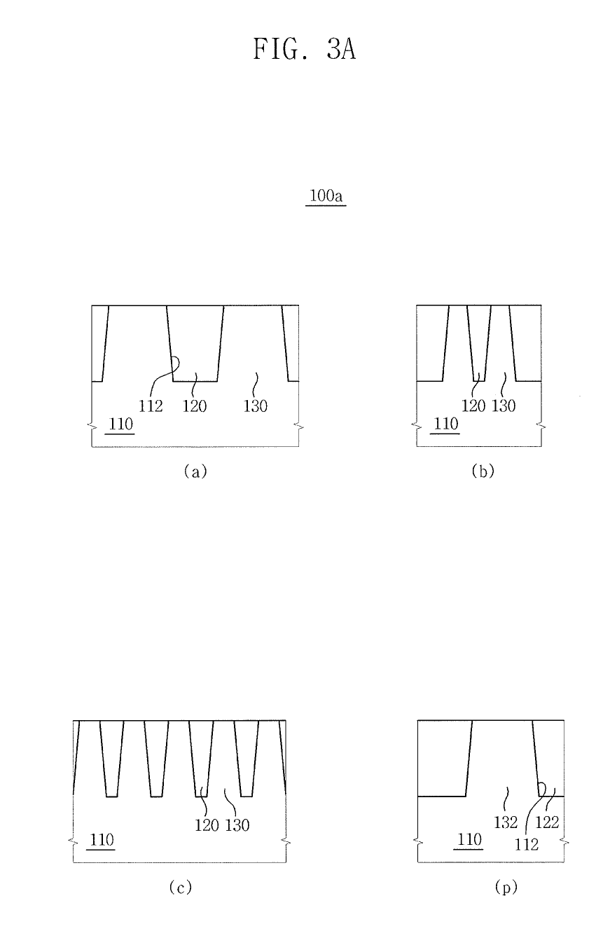

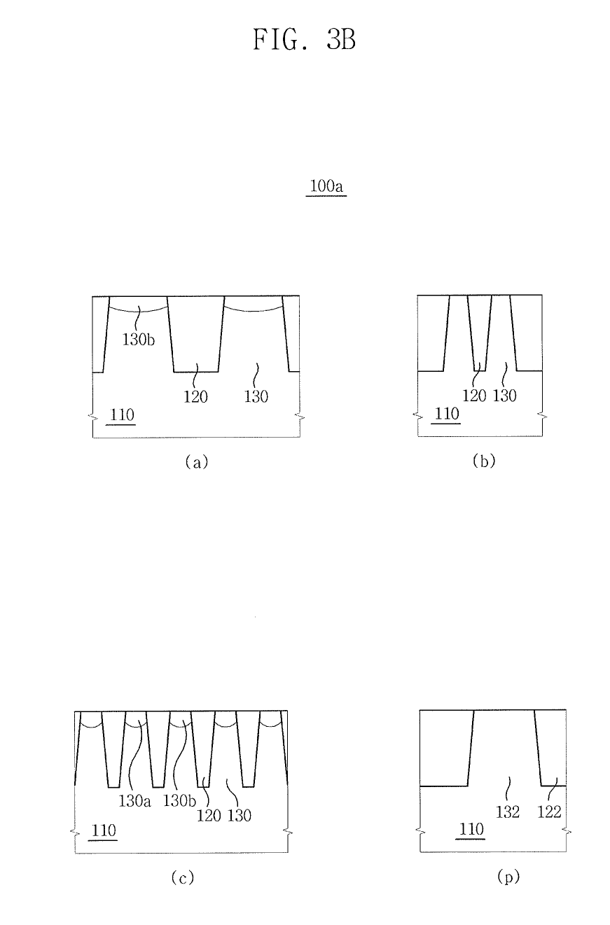

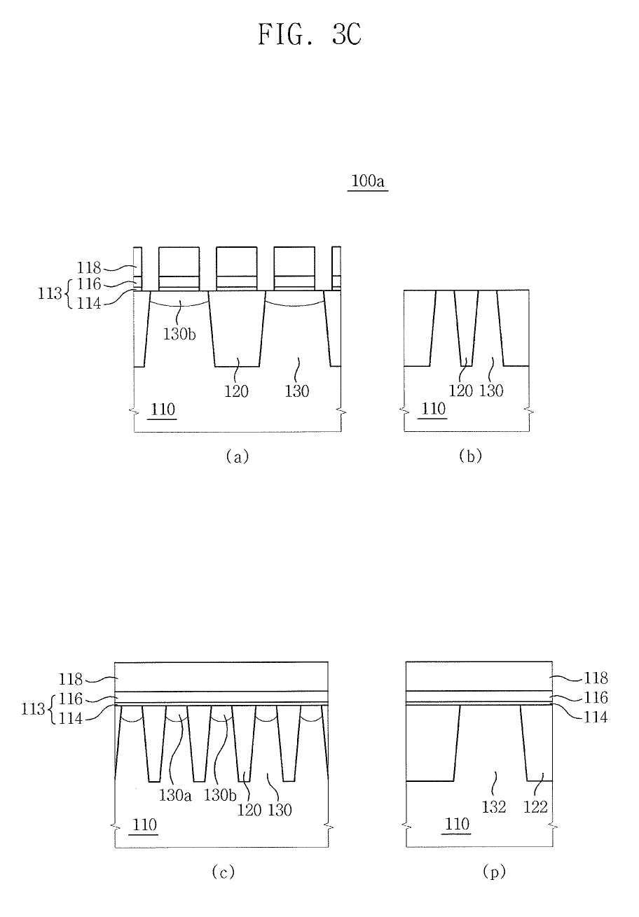

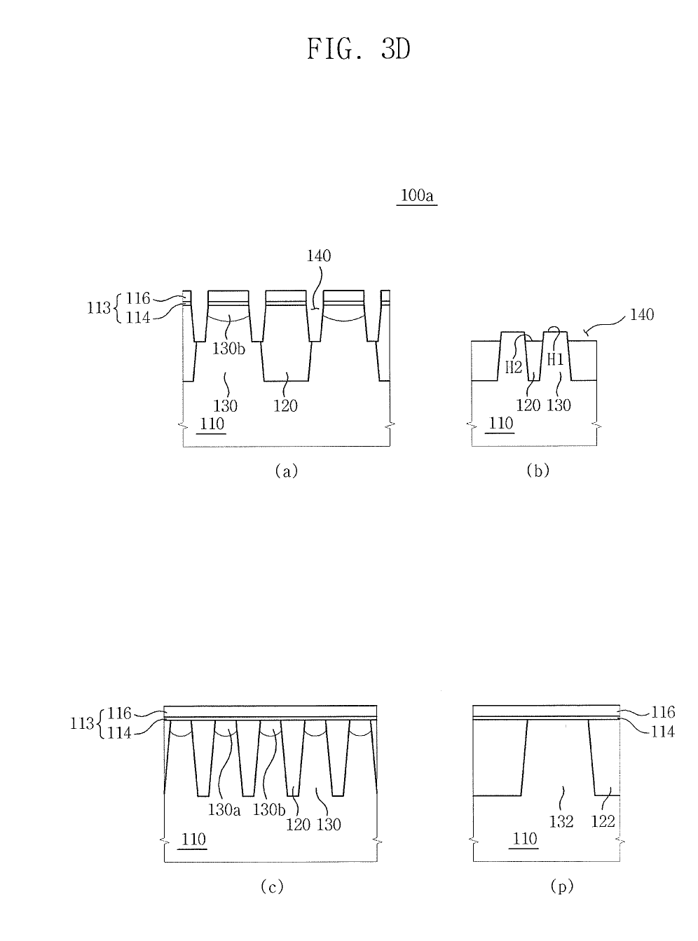

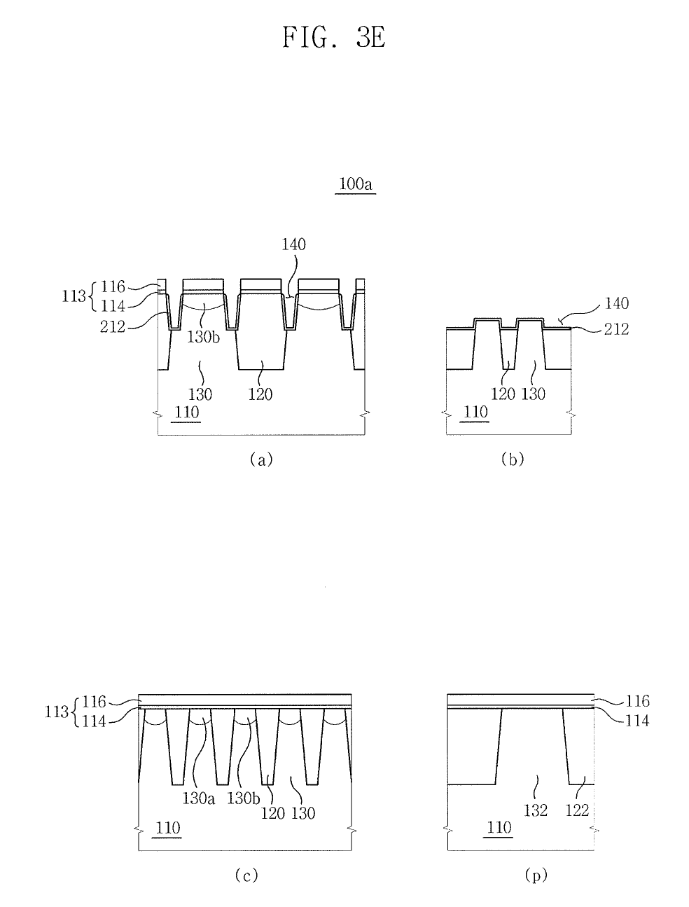

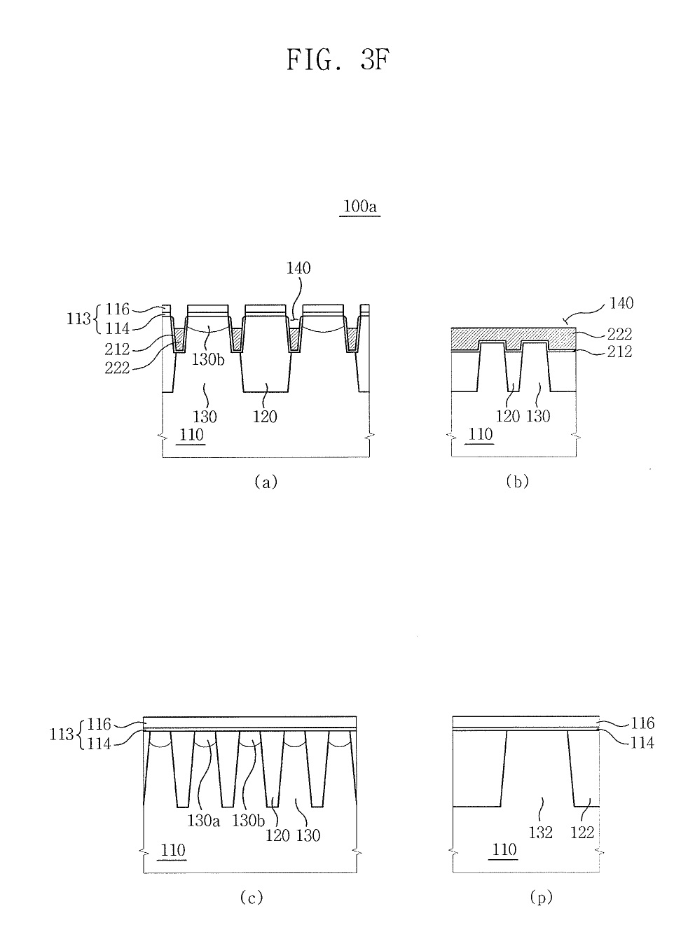

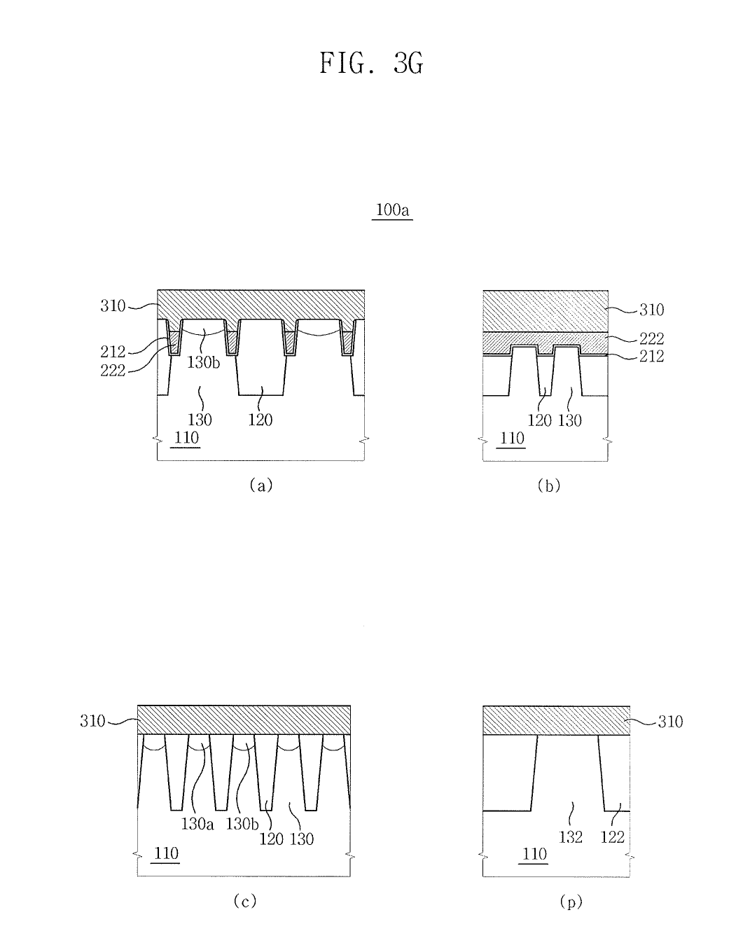

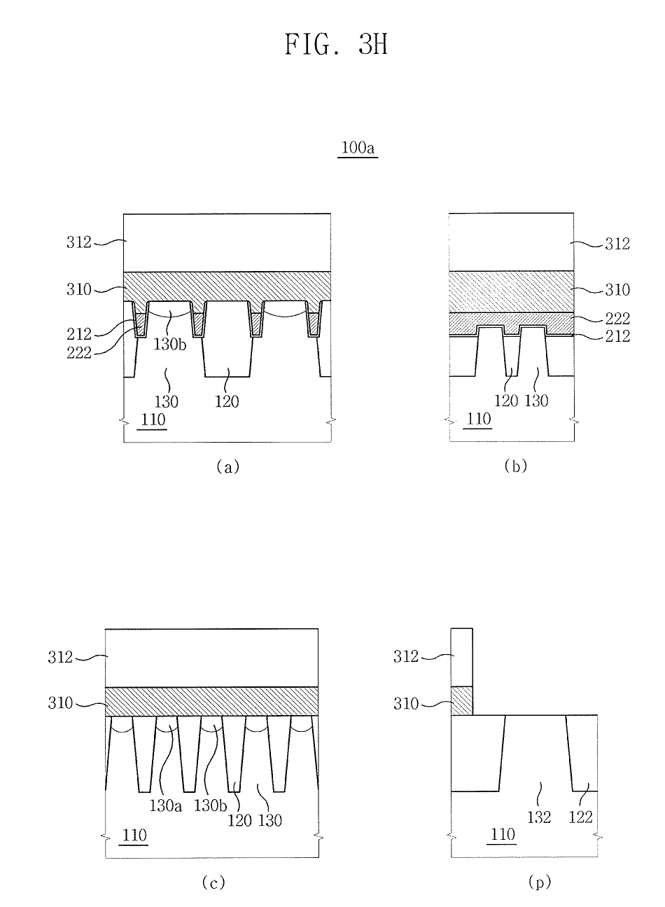

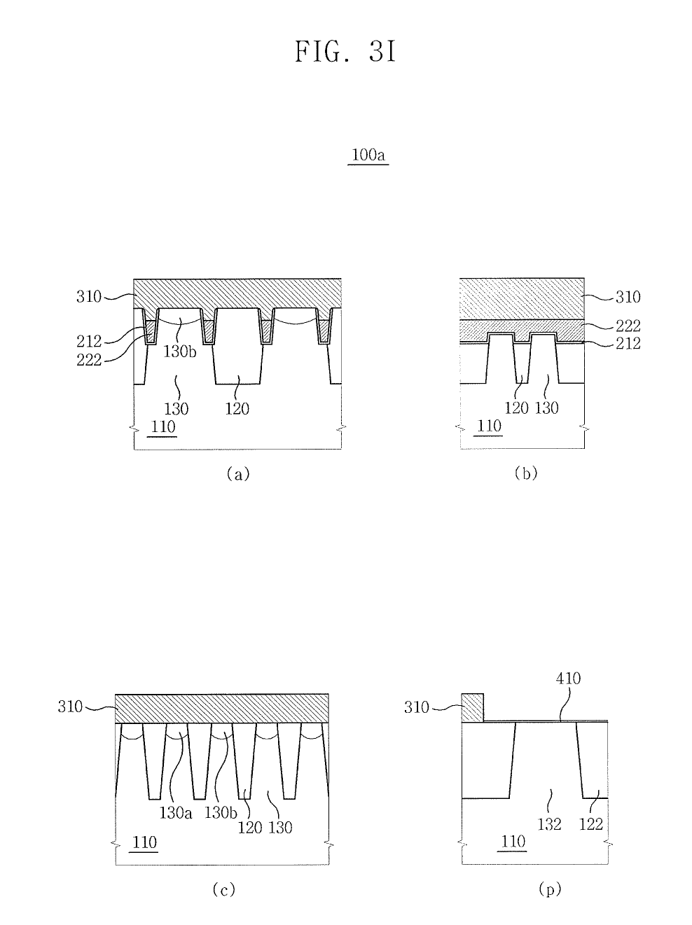

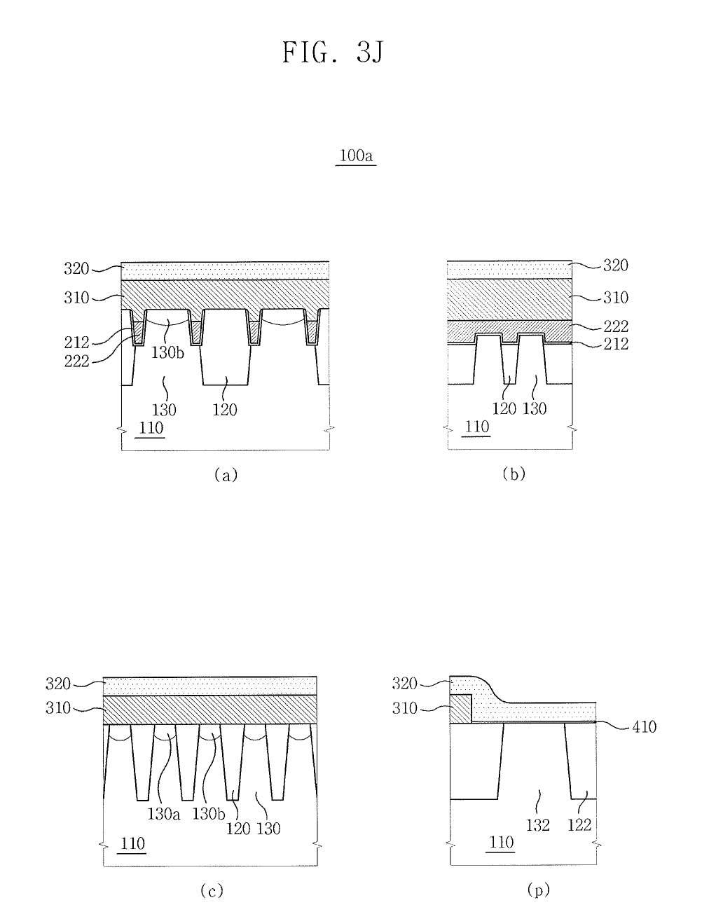

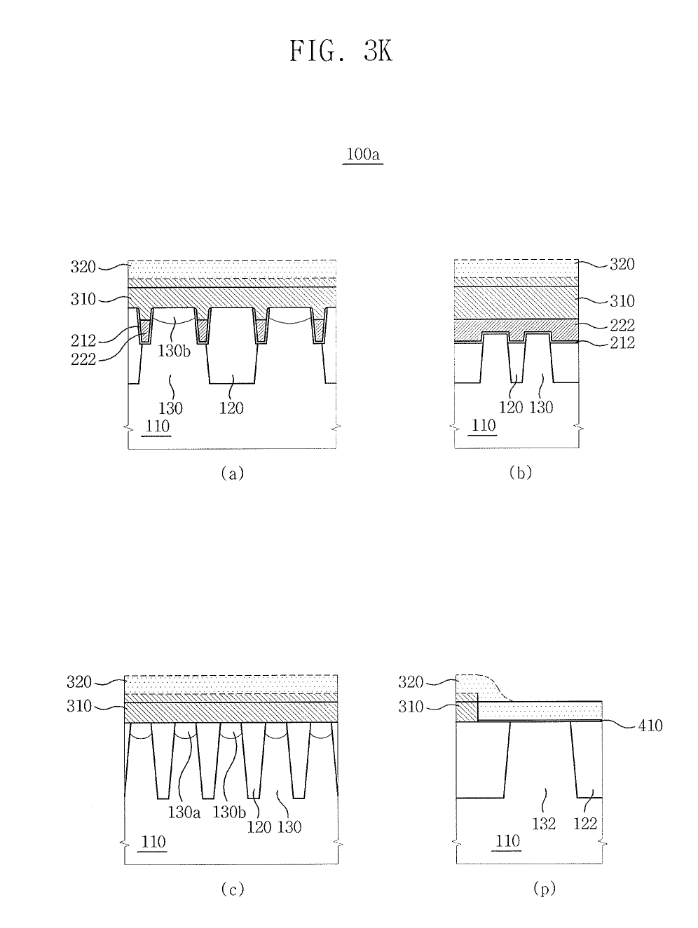

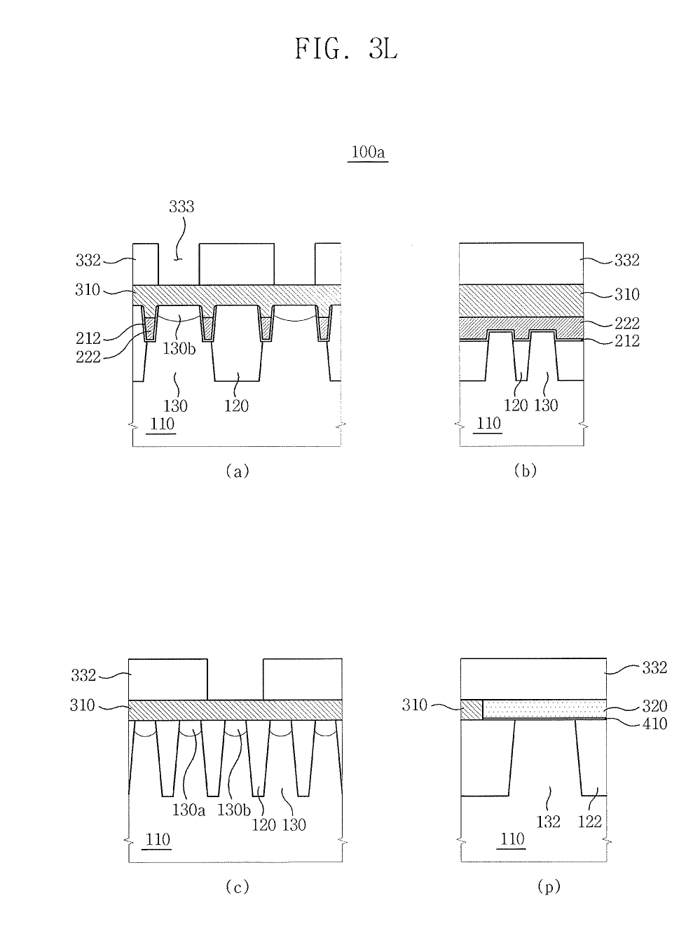

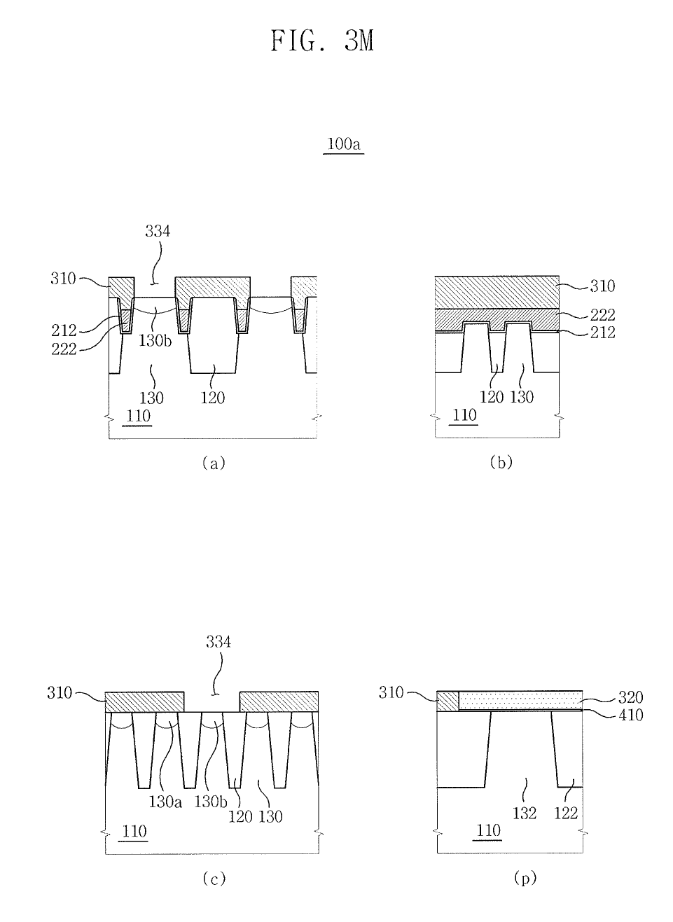

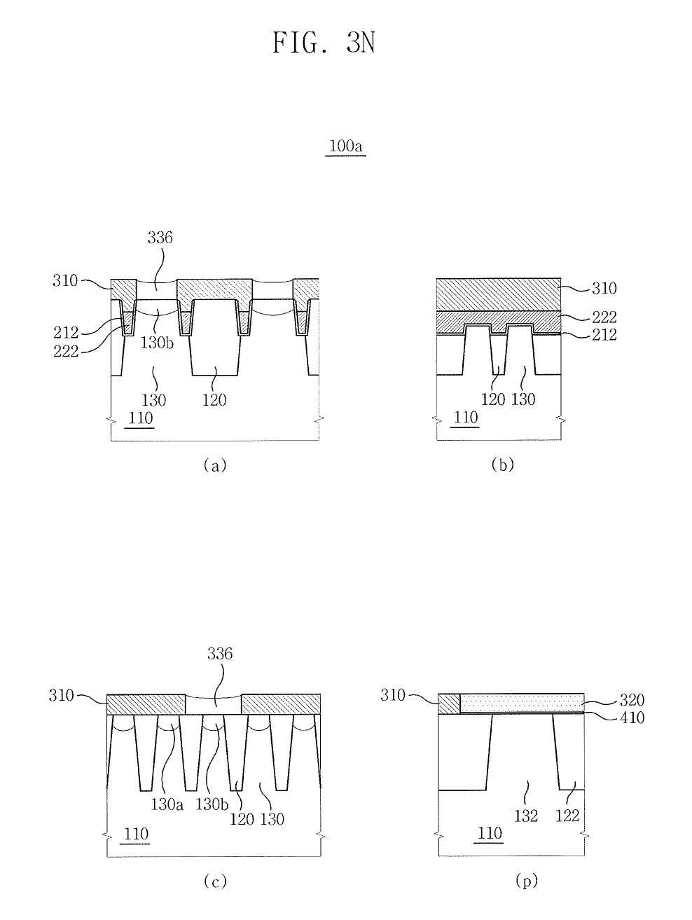

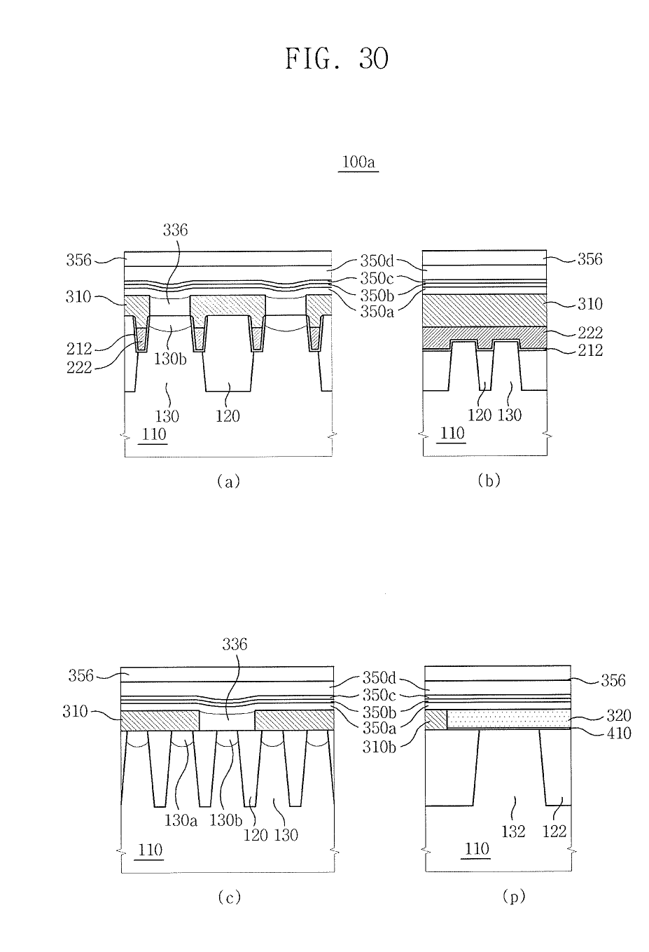

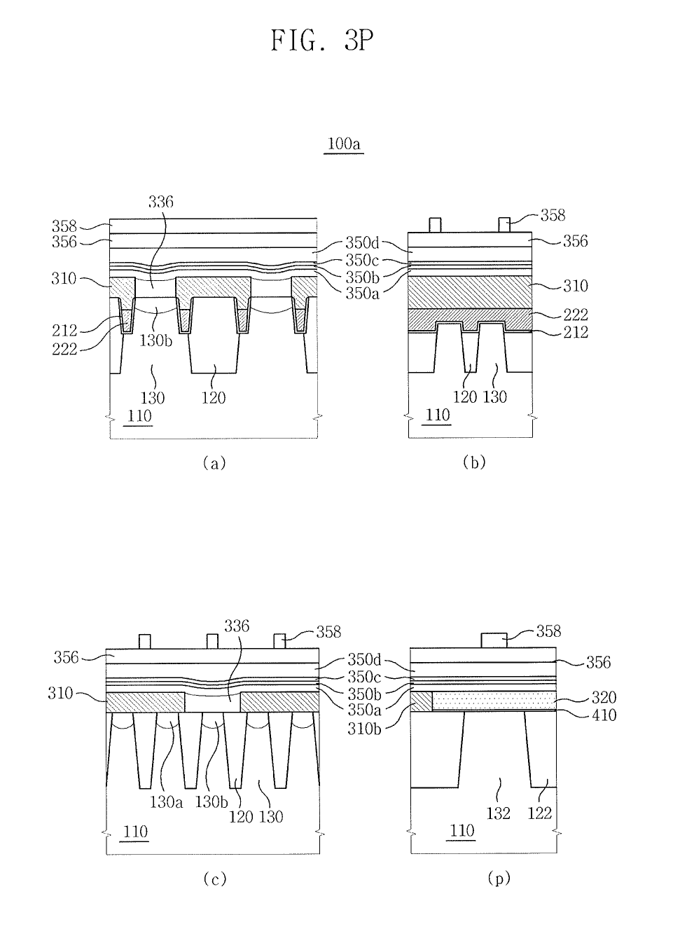

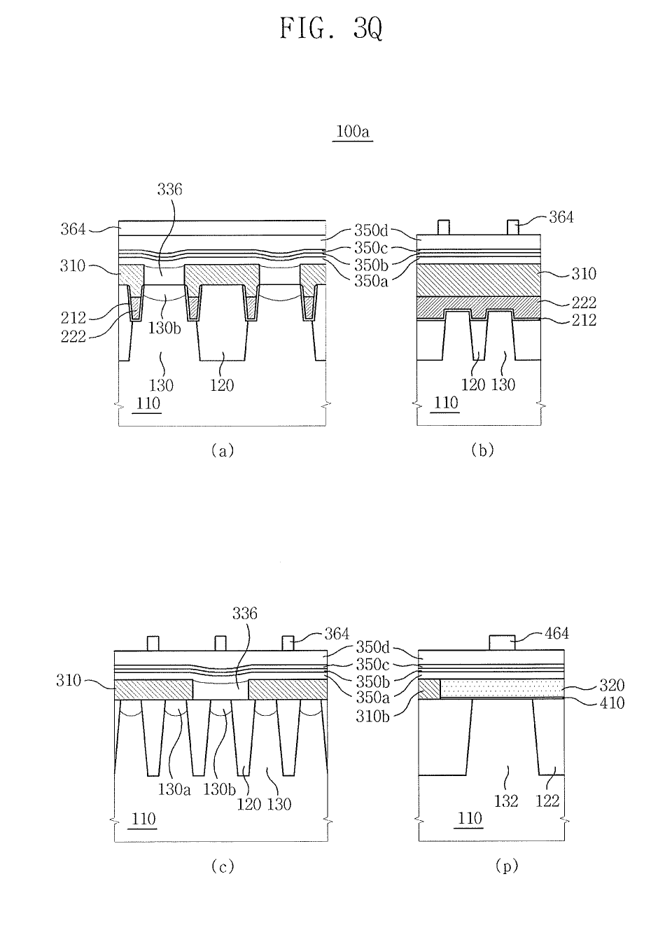

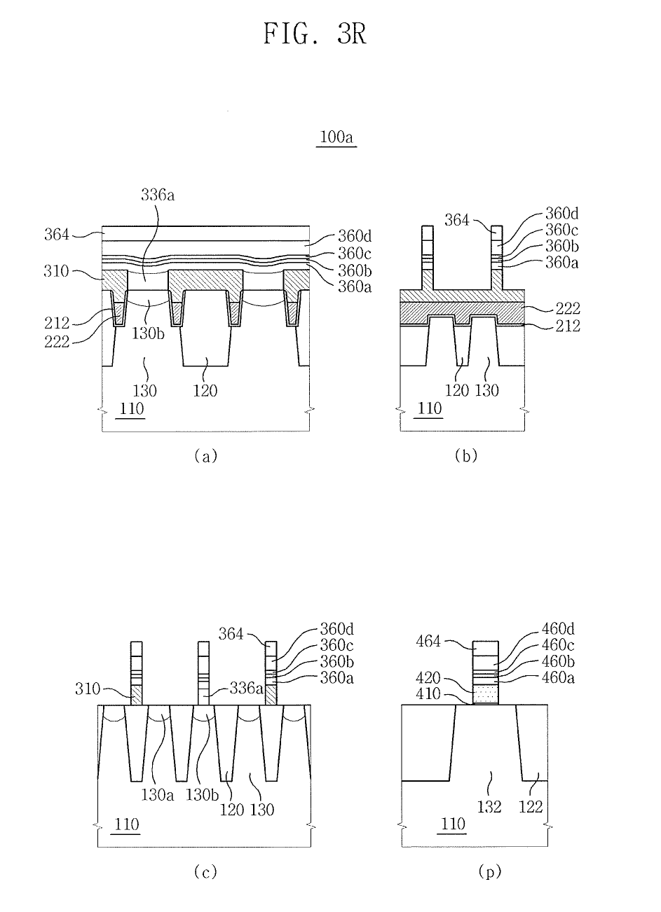

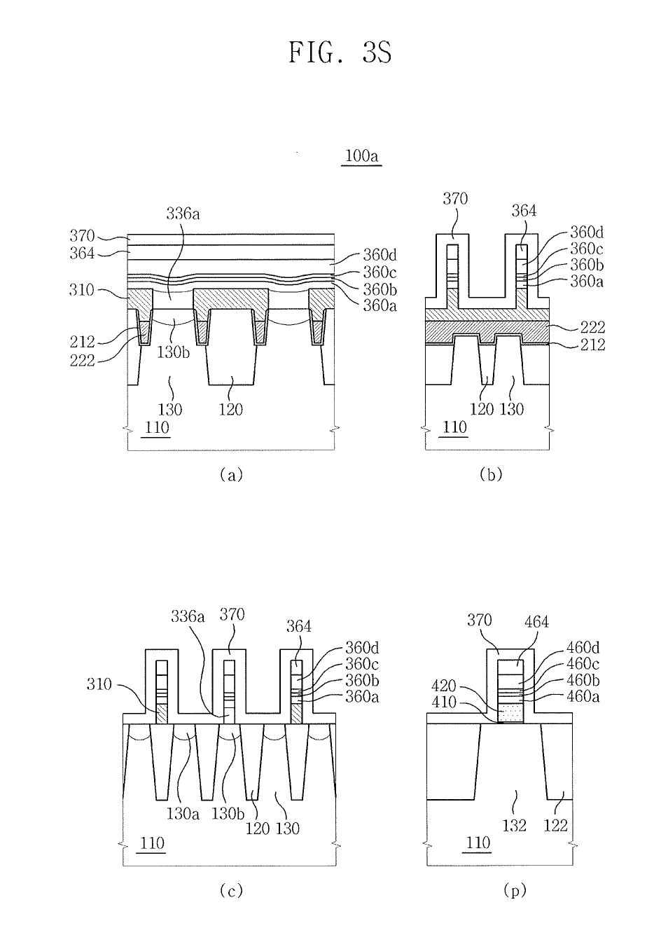

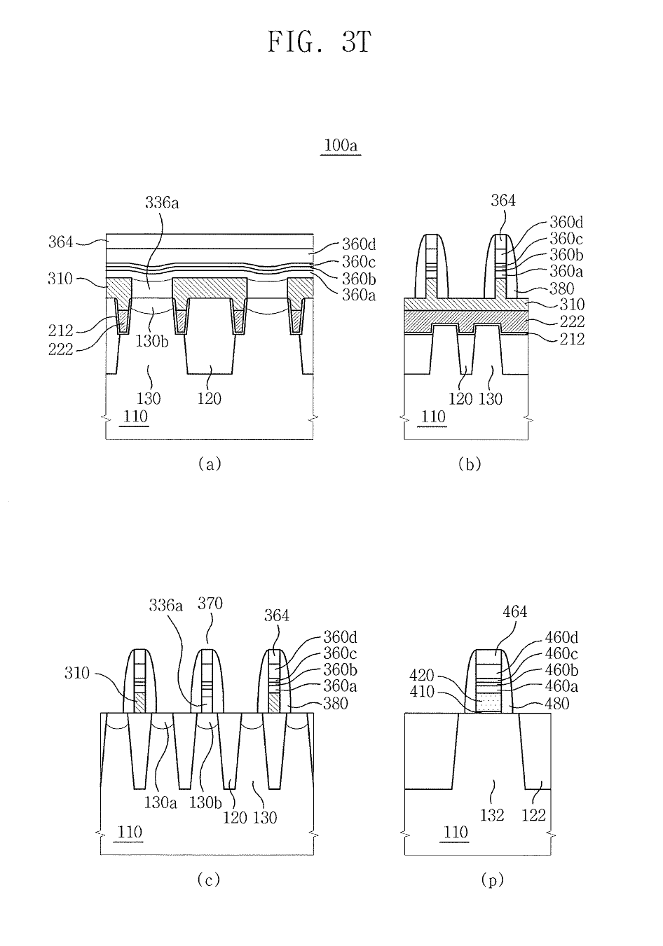

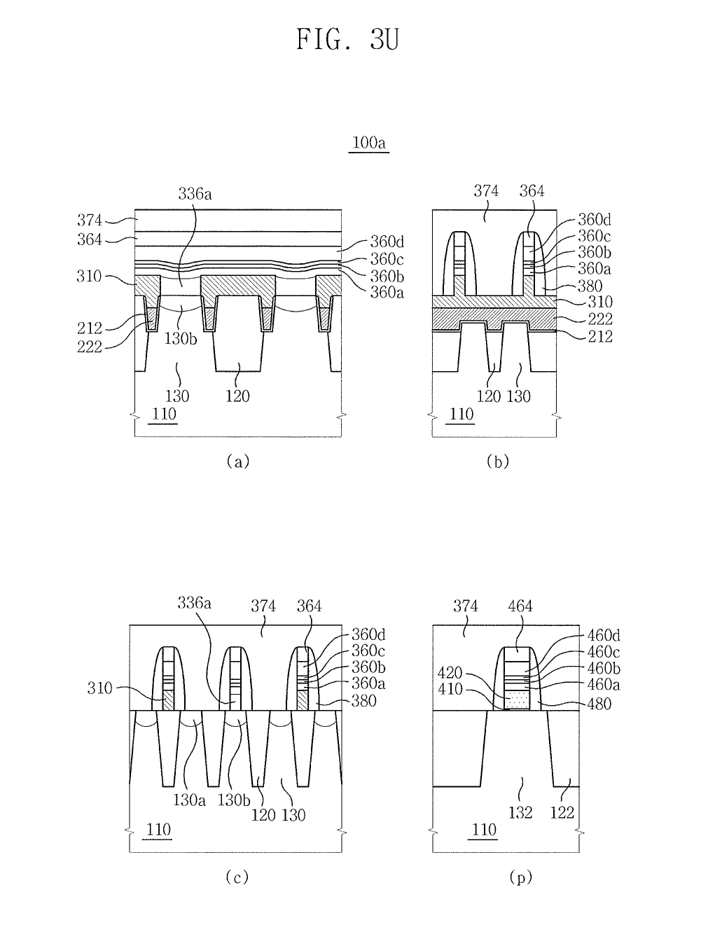

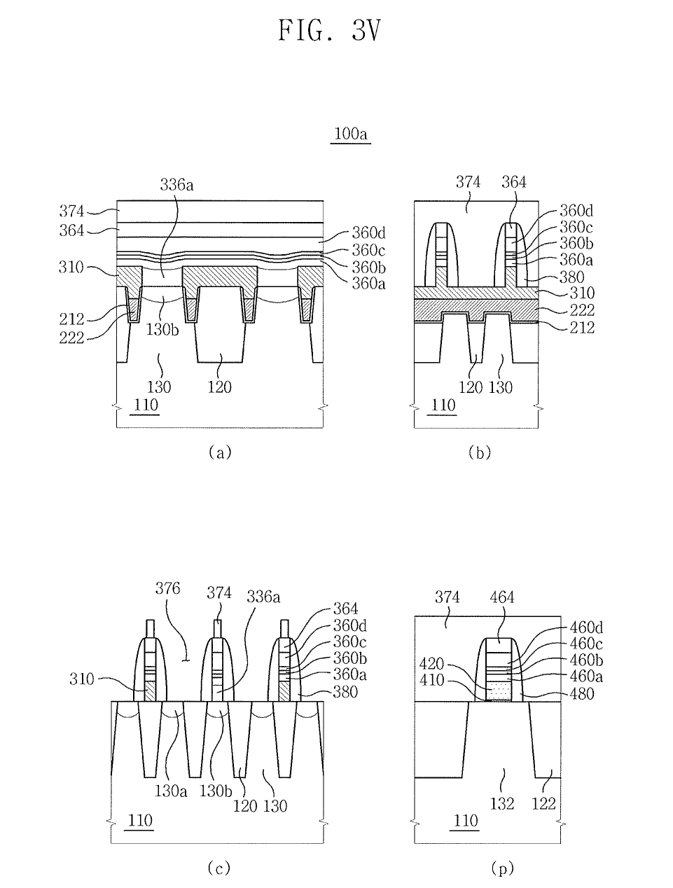

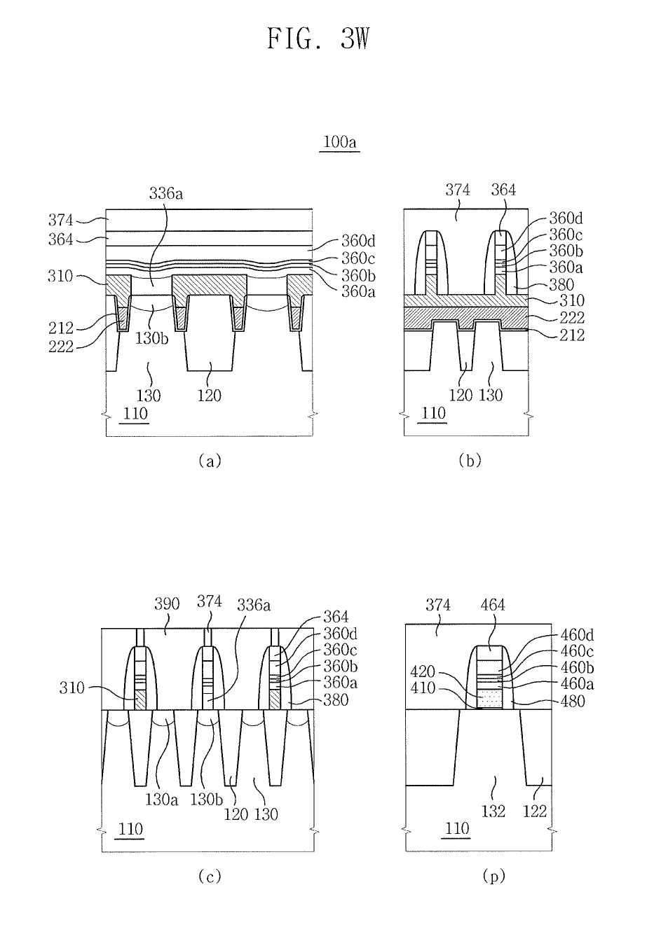

FIGS. 3A through 3W illustrate longitudinal sectional views depicting stages in a method of fabricating a semiconductor device according to an exemplary embodiment, which are taken along lines A-A′, B-B′, and C-C′ of FIG. 1A and line P-P′ of FIG. 1B.

Referring to FIG. 3A, an isolation process may be performed on the entire substrate 110 including a cell area CA and a peripheral area PA. Isolation regions may be formed in the substrate 110 using, e.g., a shallow trench isolation (STI) process. For example, isolation trenches 112 may be formed in the substrate 110. The isolation trenches may be filled, e.g., completely filled, with an insulating material. Thus, cell isolation regions 120 may be formed in the cell area CA to define a cell active region 130. Simultaneously, a peripheral isolation region 122 may be formed in the peripheral area PA to define a peripheral active region 132. The substrate 110 may include, e.g., single crystalline silicon and/or silicon germanium (SiGe). The insulating material may include at least one of, e.g., tetraethyl orthosilicate (TEOS), tonen silazene (TOSZ), boron phosphorus silicate glass (BPSG), undoped silicate glass (USG), and/or a high-density plasma (HDP) oxide, which has an insulation function.

Referring to FIG. 3B, an ion implantation process may be performed in the substrate 110, e.g., in regions between adjacent cell isolation regions 120 in the cell area CA. A portion of a trench mask (refer to 113 in FIG. 3C) may remain on the substrate 110 or a first interlayer insulating layer (refer to 310 in FIG. 3G) may be formed during subsequent photolithography and etching processes, and the ion implantation process may be conducted before forming the trench mask 113 or the first interlayer insulating layer 310. Based on the ion implantation process, a cell source region 130a and a cell drain region 130b may be formed in the cell active region CA.

Referring to FIG. 3C, the trench mask 113 may be formed on the substrate 110 using, e.g., photolithography and etching processes. The trench mask 113 may include, e.g., a pad oxide pattern 114 and a mask pattern 116. For example, the pad oxide pattern 114 may include, e.g., a thermal oxide having a thickness of approximately 50 Å to 150 Å. The mask pattern 116 may be used as an etch mask during a subsequent etching process. The mask pattern 116 may be formed of a material having, e.g., a high etch selectivity with respect to the substrate 110. The mask pattern 116 may include, e.g., silicon nitride. Alternatively, the mask pattern 116 may include, e.g., a SOH (spin-on-hardmask) layer. The SOH layer may include, e.g., an organic compound containing a hydrocarbon compound (e.g., phenyl/benzene, or naphthalene) having aromatic rings or derivatives thereof. The mask pattern 116 may be formed using, e.g., a low-pressure chemical vapor deposition (LPCVD) process to a thickness of approximately 1,000 Å to 1,500 Å. The pad oxide pattern 114 and the mask pattern 116 may be formed by a photolithography process using, e.g., a first photoresist pattern 118 as a patterning mask to partially expose the cell active region 130 and the cell isolation region 120. Subsequently, the first photoresist pattern 118 may be removed, e.g., the first photoresist pattern 118 may be removed prior to the subsequent manufacturing stage.

Referring to FIG. 3D, the gate buried trench 140 may be formed in the cell area CA using, e.g., a recess process. During the forming of the gate buried trench 140, the pad oxide pattern 114 and the mask pattern 116 may remain on the substrate 110. For example, an exposed portion of the substrate 110 may be removed using the mask pattern 116 as an etch mask to, e.g., a depth of approximately 2,000 Å to 10,000 Å. Due to the recess process, both the cell active region 130 and the cell isolation region 120 may be partially removed to form the gate buried trench 140 therebetween. According to an exemplary embodiment, the cell active region 130 may be removed more than the cell isolation region 120. The gate buried trench 140, which may be a space formed for a buried gate electrode to be formed therein, may have a protruding fin structure as needed. The cell isolation region 120 may have a top surface level H2 lower than a top surface level H1 of the cell active region 130, e.g., so that the cell active region 130 may have the protruding fin structure.

Referring to FIG. 3E, the cell gate insulating layer 212 may be formed within the gate buried trench 140. For example, the cell gate insulating layer 212 may be formed using a CVD process. Alternatively, the cell gate insulating layer 212 may be conformally formed using, e.g., a thermal deposition process on an inner wall of the gate buried trench 140 along profiles of a bottom and sidewall of the gate buried trench 140. The cell gate insulating layer 212 may include, e.g., silicon oxide.

Referring to FIG. 3F, the cell gate conductive pattern 222 may be formed on the cell gate insulating layer 212 using, e.g., a CVD process or a sputtering process, to fill the gate buried trench 140. The cell gate conductive pattern 222 may include, e.g., doped polysilicon, a metal, and/or a metal compound. The cell gate conductive pattern 222 may have a top surface level lower than a top surface level of the substrate 110, e.g., the cell gate conductive pattern 222 may only fill the lower portion of the gate buried trench 140. Thereafter, the mask pattern 116 may be removed. The pad oxide pattern 114 may be removed or left. In the drawings, which illustrate an exemplary embodiment, the pad oxide pattern 114 is removed prior to the subsequent manufacturing stage.

Referring to FIG. 3G, the first interlayer insulating layer 310 may be formed on the substrate 110. An insulating material may be, e.g., blanket-deposited on the substrate 110 to form the first interlayer insulating layer 310. The first interlayer insulating layer 310 may be formed on a top surface, e.g., the uppermost surface, of the substrate 110 to a thickness of approximately 300 Å to 700 Å. A portion of the first interlayer insulating layer 310 may fill the gate buried trench 140. The first interlayer insulating layer 310 may be formed of the same insulating material as or a similar insulating material to the pad oxide pattern 114 disposed on the substrate 110. Accordingly, if the pad oxide pattern 114 remains on the substrate 110, a boundary between the first interlayer insulating layer 310 and the pad oxide pattern 114 may disappear after forming the first interlayer insulating layer 310. Accordingly, the pad oxide pattern 114 is not separately shown in FIG. 3G. When the first interlayer insulating layer 310 includes, e.g., silicon oxide, the first interlayer insulating layer 310 may have a lower dielectric constant than, e.g., a silicon nitride layer. According to an exemplary embodiment, the first interlayer insulating layer 310 may include at least one of, e.g., silicon carbonic hydroxide (SiCHO), TEOS, USG, and BPSG.

Referring to FIG. 3H, a peripheral area open mask 312 may be formed using, e.g., a photolithography process, to cover the cell area CA and expose the peripheral area PA. The peripheral area open mask 312 may include, e.g., a photoresist pattern. The first interlayer insulating layer 310 of the peripheral area PA may be wholly or partially removed using the peripheral area open mask 312. Subsequently, the peripheral area open mask 312 may be removed.

Referring to FIG. 3I, a peripheral gate insulating layer 410 of a peripheral transistor may be formed on the peripheral active region 132. The peripheral gate insulating layer 410 may include, e.g., silicon thermal oxide formed using a thermal deposition process. The peripheral gate insulating layer 410 may be formed to, e.g., a thickness of approximately 30 Å to 70 Å. During the stage of forming the peripheral gate insulating layer, the insulating layer may be formed on the first interlayer insulating layer 310. According to an exemplary embodiment, the peripheral gate insulating layer 410 may be formed of the same material as or a similar material to the first interlayer insulating layer 310 so that the a boundary between the insulating layer forming the peripheral gate insulating layer on the first interlayer insulating layer 310 may disappear. Therefore, the peripheral gate insulating layer 410 may be omitted in the drawings, e.g., in the cell area CA.

Referring to FIG. 3J, a first conductive layer 320 may be, e.g., blanket-formed on the substrate 110. The first conductive layer 320 may be formed to a thickness of approximately 300 Å to 600 Å. The first conductive layer 320 may have an upper region formed of carbon (C) to a predetermined depth. The first conductive layer 320 may be used to, e.g., form a gate electrode of the peripheral transistor in the peripheral area PA. According to an exemplary embodiment, thereafter, an ion implantation process for applying conductivity to the first conductive layer 320 may be further performed.

Referring to FIG. 3K, the first conductive layer 320 may be blanket-planarized using, e.g., a chemical mechanical polishing (CMP) process or an etchback process. The first conductive layer 320 may be removed from the cell area CA to expose the first interlayer insulating layer 310. The thickness of the first interlayer insulating layer 310 may be reduced, e.g., during the removal process. After removing the first conductive layer 320 in the cell area CA, the first conductive layer 320 in the peripheral area PA may be substantially coplanar with the interlayer insulating layer 310.

Referring to FIG. 3L, a plug mask pattern 332 may be formed on the planarized first interlayer insulating layer 310 and the conductive layer 320. The plug mask pattern 332 may include, e.g., a photoresist pattern. The plug mask pattern 332 may include openings 333 in the cell area CA, e.g., configured to open regions of the first interlayer insulating layer 310 corresponding to the cell drain regions 130b.

Referring to FIG. 3M, the first interlayer insulating layer 310 may be etched using, e.g., the plug mask pattern 332 as an etch mask. Accordingly, bit contact holes 334 to partially expose the cell drain region 130b may be formed. Subsequently, the plug mask pattern 332 may be removed. Thus, the first interlayer insulating layer 310 partially exposing the cell drain region 130b may be formed. Here, a bottom surface of the bit contact hole 334 may be recessed to a lower level than other surfaces of the substrate 110.

Referring to FIG. 3N, a preliminary bit contact plug 336 may be formed to be directly electrically and/or physically connected to the cell drain region 130b. For example, the formation of the preliminary bit contact plug 336 may include blanket-forming a conductive material on the first interlayer insulating layer 310 to fill the bit contact hole 334 and planarizing the conductive material until a top surface of the first interlayer insulating layer 310 is exposed. The conductive material may include, e.g., doped polysilicon and/or a metal.

Referring to FIG. 3O, a deposition process may be performed in both the cell area CA and the peripheral area PA so that, e.g., a lower metal silicide layer 350a, a barrier layer 350b, an upper metal silicide layer 350c, an electrode layer 350d, and a hard mask layer 356 can be sequentially formed on the first interlayer insulating layer 310 and the preliminary bit contact plug 336. Each of the lower metal silicide layer 350a and the upper metal silicide layer 350c may include, e.g., a metal silicide material. The barrier layer 350b may include, e.g., titanium nitride (TiN). The electrode layer 350d may include, e.g., a metal and/or a metal nitride.

Referring to FIG. 3P, a bit mask 358 may be formed on the hard mask layer 356 using, e.g., a photolithography process. For example, a photoresist layer (not shown) may be coated on the hard mask layer 356, and a portion of the photoresist layer may be selectively removed using a photolithography process to form the bit mask 358.

Referring to FIG. 3Q, a bit hard mask pattern 364 may be formed in the cell area CA. Simultaneously, a peripheral gate hard mask pattern 464 may be formed in the peripheral area PA. The bit hard mask pattern 364 and the peripheral gate hard mask pattern 464 may be formed by partially removing the hard mask layer 356 using the bit mask 358 in FIG. 3P as an etch mask. The bit mask 358 may be removed after forming the hard mask layer 356.

Referring to FIG. 3R, the electrode layer 350d, the upper metal silicide layer 350c, the barrier layer 350b, the lower metal silicide layer 350a, and the preliminary bit contact plug 336 may be selectively removed using the bit hard mask pattern 364 and the peripheral gate hard mask pattern 464 as an etch mask. A patterning process may be performed on the cell area CA using the bit hard mask pattern 364 as an etch mask, thereby sequentially forming the bit contact plug 336a, the bit lower metal silicide pattern 360a, the bit barrier pattern 360b, the bit upper metal silicide pattern 360c, and the bit electrode pattern 360d. Simultaneously, a patterning process may be performed on the peripheral area PA using the peripheral gate hard mask pattern 464 as an etch mask, thereby sequentially forming the peripheral gate insulating layer 410, the first peripheral gate conductive pattern 420, the lower peripheral gate metal silicide pattern 460a, the peripheral gate barrier pattern 460b, the upper peripheral gate metal silicide pattern 460c, and the peripheral gate electrode pattern 460d. During the pattern process, the first interlayer insulating layer 310 may be etched, e.g., a predetermined depth of the first interlayer insulating layer 310 may be etched, to form the upper insulation region T of the first interlayer insulating layer 310.

Referring to FIG. 3S, a spacer insulating layer 370 may be formed on both the cell area CA and the peripheral area PA of the substrate 110. The spacer insulating layer 370 may include, e.g., a nitride layer formed using a CVD process. For example, the spacer insulating layer 370 may be or may include, e.g., a silicon nitride (SiN) layer and/or a silicon oxynitride (SiON) layer.

Referring to FIG. 3T, bit spacers 380 may be formed by, e.g., partially removing the spacer insulating layer 370. The bit spacers 380 may be formed, e.g., on both sidewalls of the bit hard mask pattern 364, the bit conductive pattern 360, and the bit contact plug 336a. For example, in the cell area CA, the bit spacers 380 may extend from an upper surface of the lower insulation region B of the first interlayer insulating layer 310 or the upper surface of the substrate 110 to an upper surface of the bit hard mask pattern 364. During the same process stage, e.g., simultaneously, peripheral gate spacers 480 may be formed on both sidewalls of the peripheral gate hard mask pattern 464, the second peripheral gate conductive pattern 460, the first peripheral gate conductive pattern 420, and the peripheral gate insulating layer 410. For example, in the peripheral area PA, the peripheral gate spacers 480 may extend from the upper surface of the substrate 110 to an upper surface of the peripheral gate hard mask pattern 464.

Referring to FIG. 3U, a second interlayer insulating layer 374 may be formed to cover the bit hard mask pattern 364 and the peripheral gate hard mask pattern 464. The second interlayer insulating layer 374 may cover the hard mask layer 364 in the cell area. To form the second interlayer insulating layer 374, a silicon oxide layer may be deposited on the entire surface of the substrate 110 and planarized to a predetermined height.

Referring to FIG. 3V, the second interlayer insulating layer 374 may be partially removed from the cell area CA, thereby forming storage contact holes 376. The storage contact holes 376 may be used for forming the storage contact plug 390 therein during a later stage. According to an exemplary embodiment, the bit spacers 380 adjacent to the predetermined area for forming the storage control holes 376, may function as a self-alignment mask to self-align the storage contact hole 376.

Referring to FIG. 3W, the storage contact hole 376 in the cell area CA may be filled with, e.g., a conductive material. Thereafter, a planarization process may be performed to form the storage contact plug 390. The storage contact plug 390 may be substantially coplanar with the second interlayer insulating layer 374.

Subsequently, a cylindrical storage electrode 500, e.g., as illustrated in FIG. 2, may be formed on the storage contact plug 390 in the cell area CA. Thereafter, the exemplary method of fabrication of the semiconductor device 100a of FIG. 2 may be completed.

### Method Embodiment 2

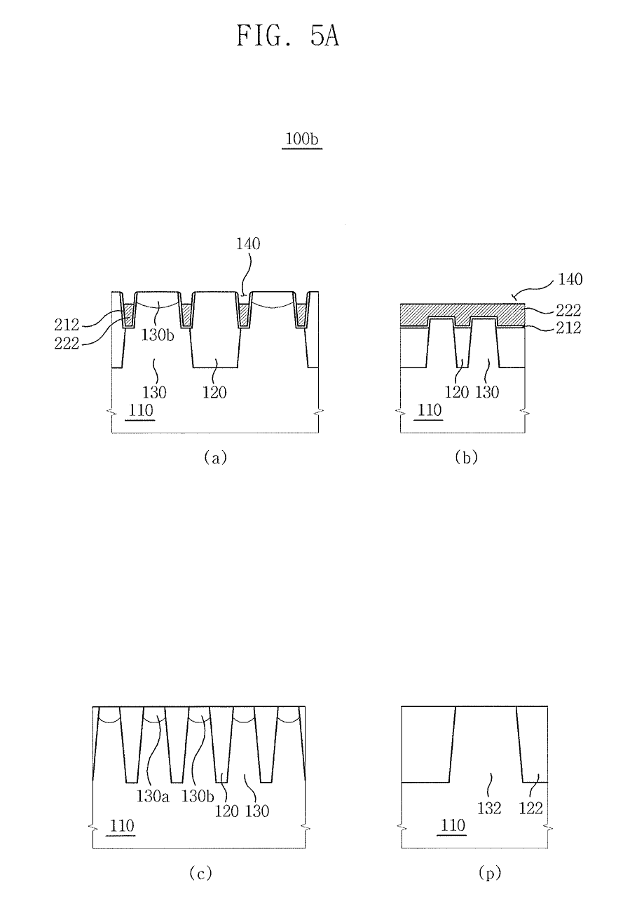

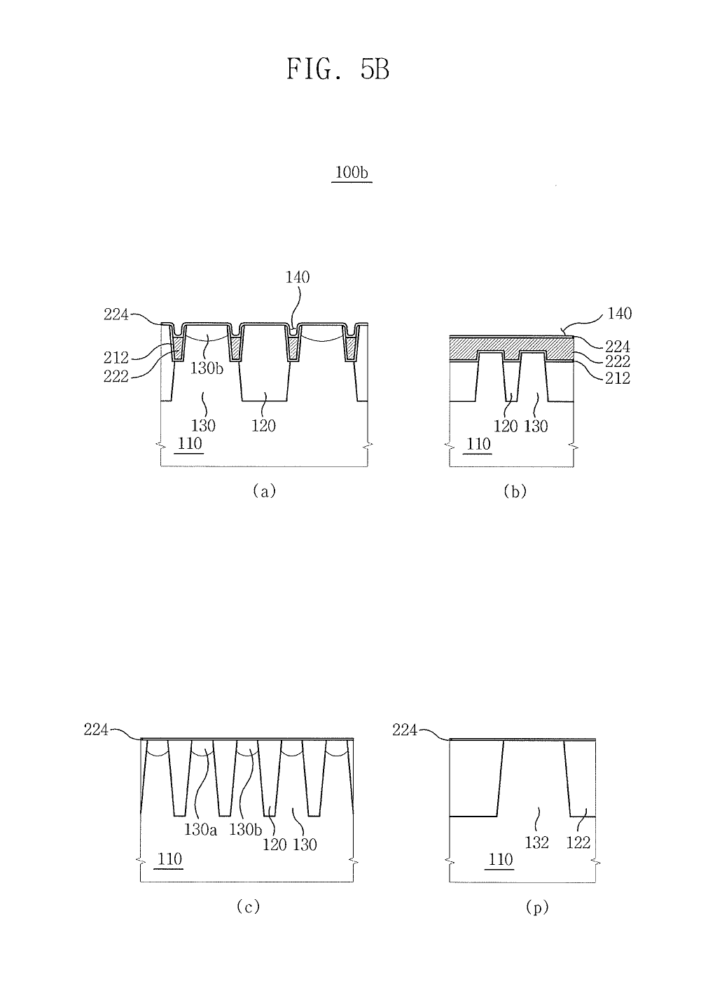

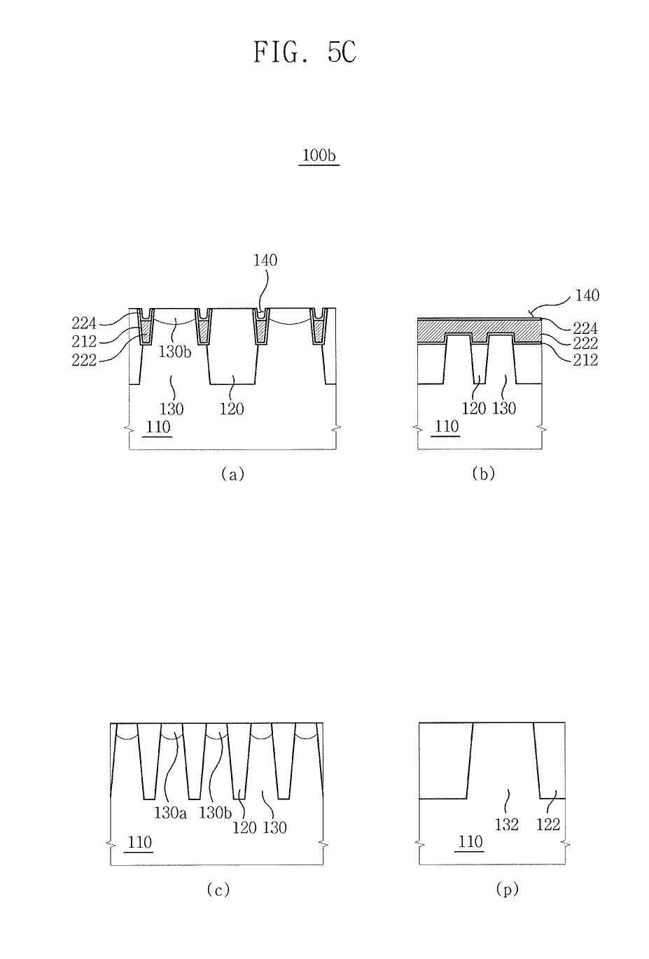

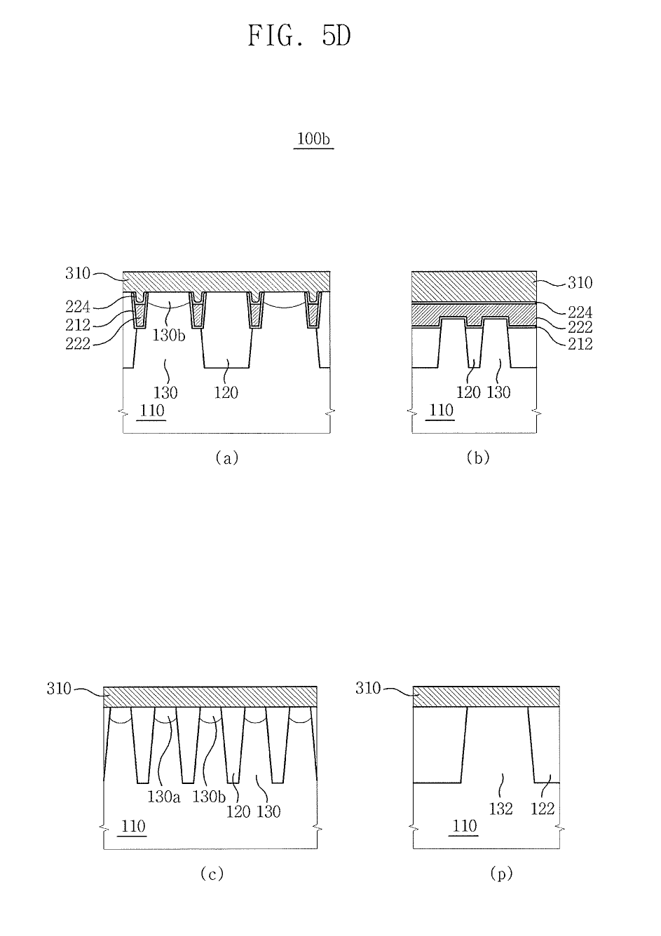

FIGS. 5A through 5D illustrate longitudinal sectional views depicting stages in methods of fabricating a semiconductor device according to another exemplary embodiment, which are taken along lines A-A′, B-B′, and C-C′ of FIG. 1A and line P-P′ of FIG. 1B.

Method Embodiment 2 may be similar to Method Embodiment 1, and only differences therebetween will be mainly described. Accordingly, a repeated description of the same components will be mostly omitted, and the same reference names and reference numerals are used to denote the same components.

Referring to FIG. 5A, after the stages described with reference to FIGS. 3A through 3F are performed, the trench mask 113 may be removed. In this case, the trench mask 113 may be wholly removed, or only the mask pattern 116 may be completely removed to partially leave the pad oxide pattern 114.

The mask pattern 116 may include an SOH layer. The SOH layer may be, e.g., an organic compound containing a hydrocarbon compound (e.g., phenyl/benzene or naphthalene) having aromatic rings or derivatives thereof. The SOH layer may contain an organic compound at a relatively high carbon (C) content of, e.g., approximately 85% to 99% by weight, based on the total weight thereof. The SOH layer may be viscous and flowable, and the SOH layer may be formed using a spin coating process. According to an exemplary embodiment, the SOH layer may contain the relatively high carbon (C), and the SOH layer may be used as an etch mask during etching of a silicon oxide layer. Thereafter, the SOH layer may be removed, e.g., easily removed, using a wet removal process or an O₂ plasma process.

Referring to FIG. 5B, the anti-oxidation layer 224 may be formed on the cell gate conductive pattern 222. The anti-oxidation layer 224 may be formed using, e.g., a silicon nitride layer. The anti-oxidation layer 224 may reduce the possibility of and/or prevent oxidation of the cell gate conductive pattern 222. The anti-oxidation layer 224 may be deposited using a CVD process not only on the cell gate conductive pattern 222 but also on the cell gate insulating layer 212, the pad oxide pattern 114, and/or an area where the mask pattern 116 was previously formed.

Referring to FIG. 5C, the anti-oxidation layer 224 may be removed from the substrate 110. Due to an etchback process, the anti-oxidation layer 224 formed along a profile of the gate buried trench 140 may remain intact, while only the anti-oxidation layer 224 formed outside the gate buried trench 140 may be removed.

Referring to FIG. 5D, the first interlayer insulating layer 310 may be formed on the anti-oxidation layer 224 to fill the gate buried trench 140. Subsequently, the stages described with reference to FIGS. 3H through 3W may be performed. Thereafter, the exemplary method of fabrication of the semiconductor device 100b of FIG. 4 may be completed.

### Method Embodiment 3

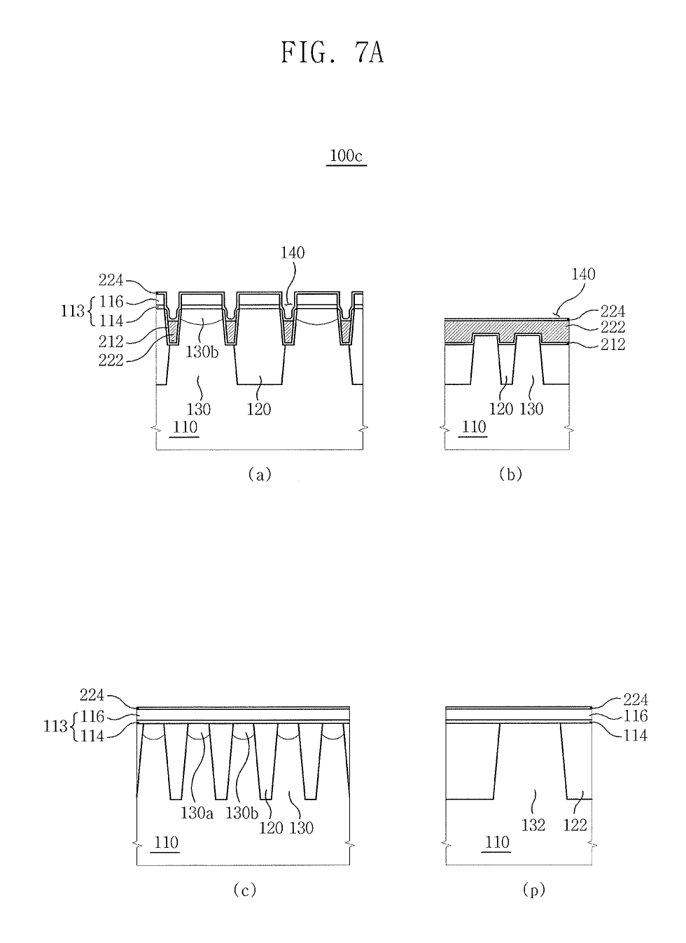

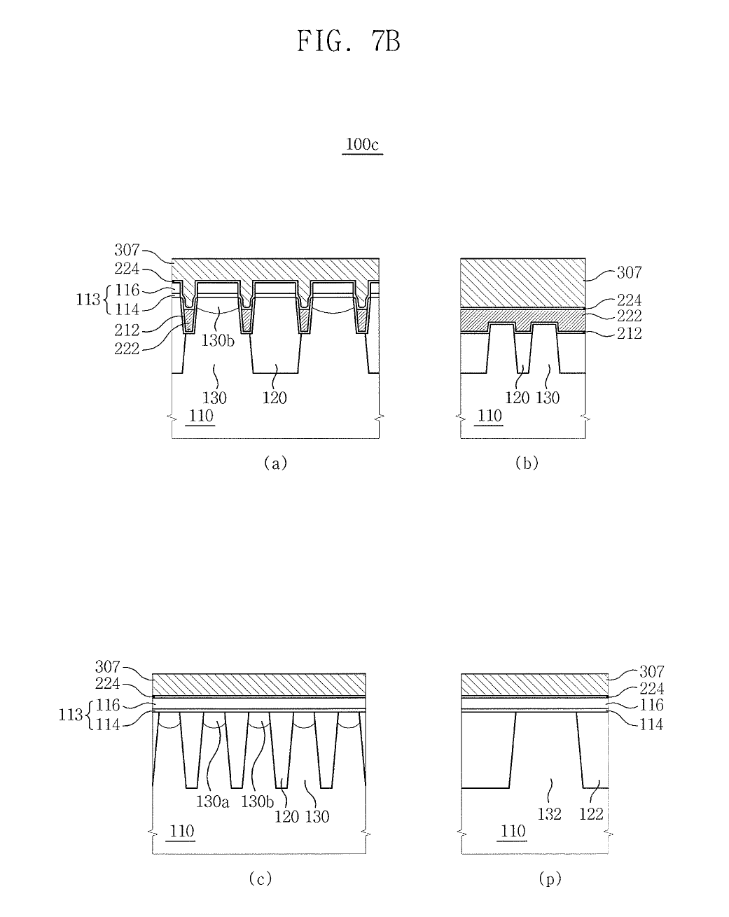

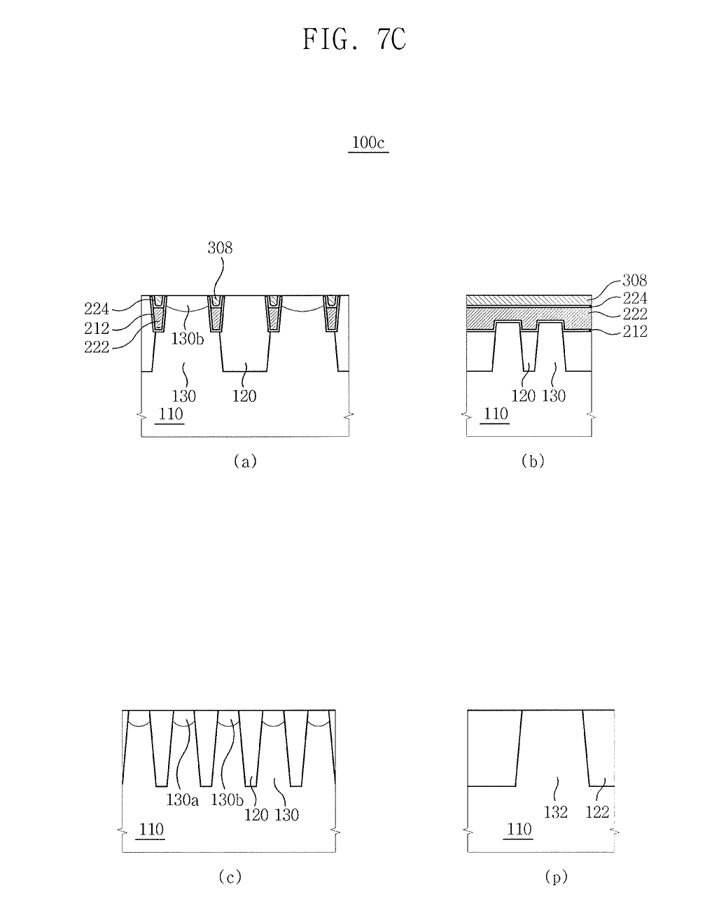

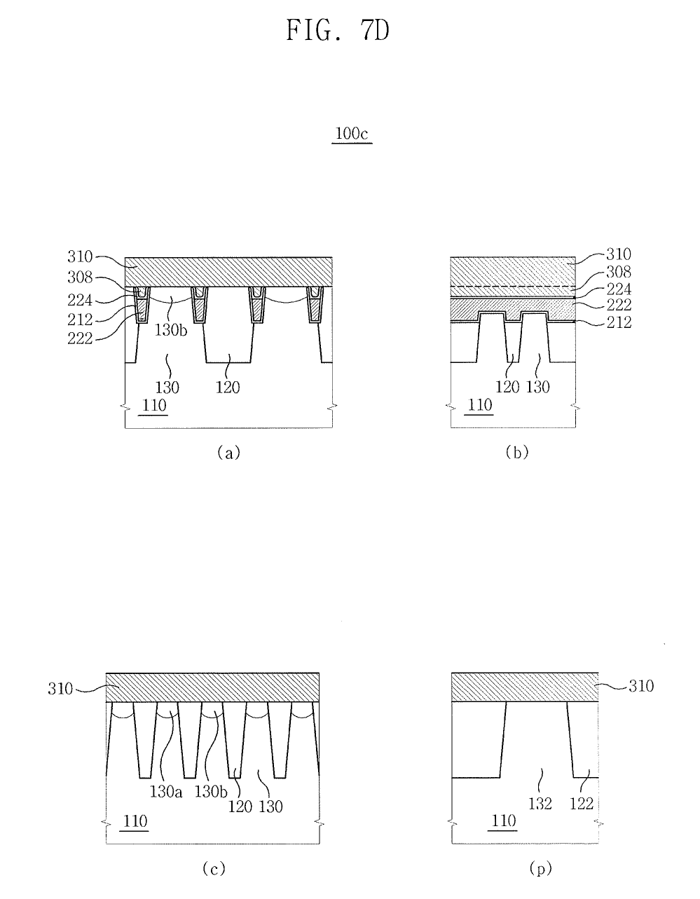

FIGS. 7A through 7D illustrate longitudinal sectional views depicting stages in methods of fabricating a semiconductor device according to another exemplary embodiment, which are taken along lines A-A′, B-B′, and C-C′ of FIG. 1A and line P-P′ of FIG. 1B.

Method Embodiment 3 may be similar to Method Embodiment 1, and only differences therebetween will be mainly described. Accordingly, a repeated description of the same components will be mostly omitted, and the same reference names and reference numerals are used to denote the same components.

Referring to FIG. 7A, after the stages described with reference to FIGS. 3A through 3F are performed, the anti-oxidation layer 224 may be formed on a cell gate conductive pattern 222. The anti-oxidation layer 224 may be formed using, e.g., a silicon nitride layer. The anti-oxidation layer 224 may reduce the possibility of and/or prevent oxidation of the cell gate conductive pattern 222. The anti-oxidation layer 224 may be formed using, e.g., a CVD process on the cell gate conductive pattern 222, on the cell gate insulating layer 212, and on the mask pattern 116. In accordance with an exemplary embodiment, removal of the pad oxide pattern 114 and the mask pattern 116 may not be performed prior to forming the anti-oxidation layer 224.

Referring to FIG. 7B, a capping insulating material 307 may be formed on the anti-oxidation layer 224 to fill, e.g., completely fill, the gate buried trench 140. The capping insulating material 307 may include, e.g., a silicon oxide layer and/or a silicon oxynitride layer having a lower dielectric constant than a silicon nitride layer. The capping insulating material 307 may have, e.g., a dielectric constant of 5 or lower.

Referring to FIG. 7C, the capping insulating material 307, the mask pattern 116, and a pad oxide pattern 114 may be wholly or partially removed to form the capping insulating layers 308. The capping insulating layers 308 may remain in respective ones of the gate buried trenches 140 so that the gate buried trench 140 remains filled, e.g., completely filled. The capping insulating material 307, the mask pattern 116, and the pad oxide pattern 114 may be simultaneously or sequentially removed using at least one of a CMP process, an etchback process, and/or a wet etching process.

Referring to FIG. 7D, the first interlayer insulating layer 310 may be formed on the substrate 110. The first interlayer insulating layer 310 may be formed of the same material as or a similar material to the capping insulating layer 308. The first interlayer insulating layer 310 may include, e.g., a silicon oxide layer and/or a silicon oxynitride layer. Subsequently, the stages described with reference to FIGS. 3H through 3W may be performed. Thereafter, the exemplary method of fabrication of the semiconductor device 100c of FIG. 6 may be completed.

Applied Exemplary Embodiments

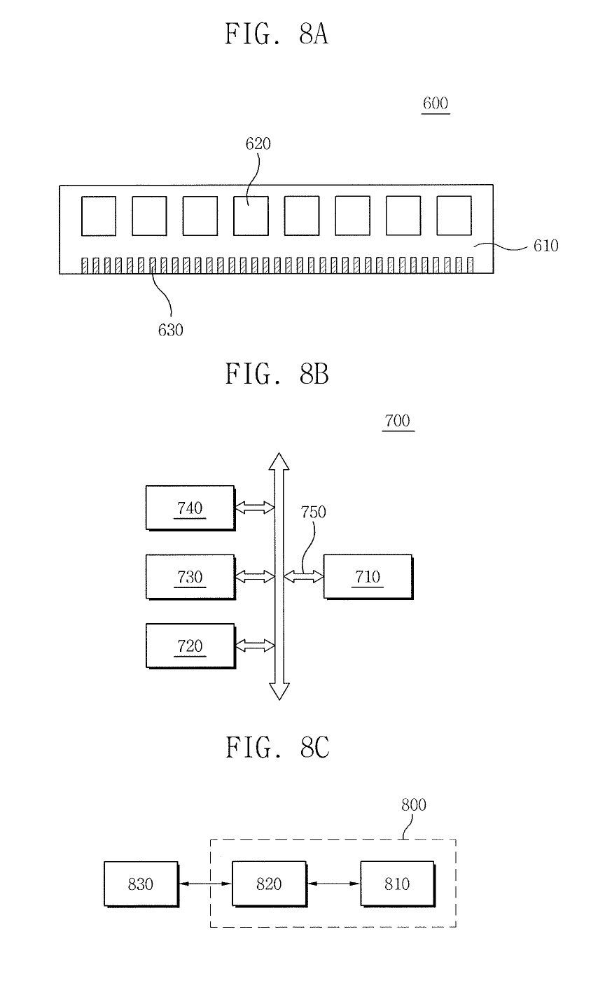

FIGS. 8A through 8C illustrate block diagrams of a semiconductor module, an electronic system, and a memory card, respectively, including various semiconductor packages according to exemplary embodiments.

Referring to FIG. 8A, the above-described semiconductor devices 100a, 100b, and 100c may be applied to a semiconductor module 600 including various kinds of semiconductor devices. The semiconductor module 600 may include, e.g., a module substrate 610, semiconductor integrated-circuit (IC) chips 620 mounted on the module substrate 610, and module contact terminals 630 disposed in a row on one side of the module substrate 610 and electrically connected to the semiconductor IC chips 620. The semiconductor IC chips 620 may be chips to which techniques related to, e.g., semiconductor devices according to exemplary embodiments may be applied. The semiconductor module 600 may be connected to an external electronic device through, e.g., the module contact terminals 630.

Referring to FIG. 8B, the above-described semiconductor devices 100a, 100b, and 100c may be applied to an electronic system 700. The electronic system 700 may include, e.g., a controller 710, an input/output (I/O) device 720, and a memory device 730. The controller 710, the I/O device 720, and the memory device 730 may be combined with one another through buses 750 capable of, e.g., providing a data transmission path. The controller 710 may include at least one of microprocessors (MPs), digital signal processors (DSPs), microcontrollers (MCs), and logic devices capable of similar functions thereto. Each of the controller 710 and the memory device 730 may include at least one of the semiconductor devices 100a, 100b, and 100c according to the exemplary embodiments. The I/O device 720 may include at least one of a keypad, a keyboard, and a display device. The memory device 730 may store data and/or commands executed by the controller 710. The memory device 730 may include a volatile memory device, such as a dynamic random access memory (DRAM), and/or a nonvolatile memory device, such as a flash memory. For example, a flash memory may be mounted in an information processing system, such as a mobile device or a desktop computer.

The flash memory may constitute a solid-state disk (SSD). The electronic system 700 may further include an interface 740 configured to transmit data to a communication network and/or receive data from the communication network. The interface 740 may be a wired/wireless interface. For example, the interface 740 may include an antenna and/or a wired/wireless transceiver. The electronic system 700 may be embodied by a mobile system, a personal computer (PC), an industrial computer, and/or a logic system capable of various functions. For example, the mobile system may be any one of a personal digital assistant (PDA), a portable computer, a web tablet, a mobile phone, a wireless phone, a laptop computer, a memory card, a digital music system, and an information transmission/receiving system.

Referring to FIG. 8C, the semiconductor devices 100a, 100b, and 100c, according to the above-described exemplary embodiments, may be provided in the type of a memory card 800. For example, the memory card 800 may include a nonvolatile memory device 810 and a memory controller 820. The nonvolatile memory device 810 and the memory controller 820 may store data and/or read the stored data. The nonvolatile memory device 810 may include at least one of nonvolatile memory devices to which techniques related to semiconductor devices according to exemplary embodiments may be applied. The memory controller 820 may read stored data and/or control the nonvolatile memory device 810 to store data in response to a read/write request of a host 830.

The names and functions of unshown or undescribed components may be easily understood with reference to other drawings of the present specification and descriptions thereof. As explained thus far, according to exemplary embodiments of methods of fabricating semiconductor devices, the at least one of the following effects may be expected. Firstly, according to an exemplary embodiment, a cell gate capping insulating layer and an interlayer insulating layer may be formed of the same material in a buried channel array transistor (BCAT) structure, and a process of depositing a capping insulating layer and an etchback process may be omitted. Secondly, a low-k silicon oxide layer may be used as the capping insulating layer in the BCAT structure, and a parasitic capacitance between a cell gate and a bit line may be reduced more than when a silicon nitride layer is used as the capping insulating layer.

By way of summation and review, with an increase in the integration density of semiconductor devices, the semiconductor devices have become more structurally elaborate. Thus, processes of fabricating the semiconductor devices have become more and more complicated. As a result, a buried channel array transistor (BCAT) technique and a 6F2 layout technique have been proposed for, e.g., improving the integration density of semiconductor device.

In a conventional BCAT structure, a gate electrode may be buried in a cell region of a substrate. A top surface of the gate electrode may be at a lower level than a top surface of the substrate. The top surface of the gate electrode may be covered with a silicon nitride layer that may function as a capping layer for protecting the gate electrode. For example, the silicon nitride layer may reduce the possibility of and/or prevent an electrical short circuit from occurring between a bit line formed on the substrate and the gate electrode. However, formation of the capping layer involves complicated processes of depositing a silicon nitride layer on the top surface of the gate electrode, etching back the silicon nitride layer until the substrate is exposed, and depositing a silicon oxide layer on the substrate. Also, since the silicon nitride layer has a high dielectric constant, a parasitic capacitance between the gate electrode and the bit line or between the gate electrode and a bit plug may be increased.

Accordingly, embodiments, e.g., the exemplary embodiments discussed above, relate to an improved semiconductor device including BCAT structure, an improved method of fabricating a semiconductor device including a BCAT structure, and a semiconductor module and electronic system including the improved semiconductor device having a BCAT structure.

Exemplary embodiments relate to simultaneously performing a process of forming a capping layer and a process of forming an interlayer insulating layer. For example, a silicon oxide layer may be formed on a gate electrode instead of a silicon nitride layer. Also, an etchback process may be omitted, and a bit line process may be performed using, e.g., the silicon oxide layer formed on a substrate as an interlayer insulating layer. Accordingly, the silicon oxide layer may function as the capping layer of the gate electrode and as the interlayer insulating layer. Thus, the manufacturing process may be simplified. Furthermore, the silicon oxide layer may serve as the capping layer and a parasitic capacitance caused by a bit line may be reduced.

Example embodiments have been disclosed herein, and although specific terms are employed, they are used and are to be interpreted in a generic and descriptive sense only and not for purpose of limitation. Although a few exemplary embodiments have been described, those skilled in the art will readily appreciate that many modifications are possible in embodiments without materially departing from the novel teachings. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of fabricating a semiconductor device, the method comprising:
forming an isolation region in a substrate to define an active region;
partially removing the active region and the isolation region to form a gate buried trench;
forming a gate insulating layer on an inner wall of the gate buried trench;
forming a gate conductive pattern on the gate insulating layer to fill the gate buried trench, a height of an uppermost surface of the gate conductive pattern being lower than a height of an uppermost surface of the substrate;
forming an interlayer insulating layer on the substrate and on the gate conductive pattern, the interlayer insulating layer including an upper insulating region and a lower insulating region, the lower insulating region filling the gate buried trench, and the upper insulating region being formed over the substrate; and
forming a bit contact plug connected to the active region through the interlayer insulating layer.

2. The method as claimed in claim 1, wherein the interlayer insulating layer includes at least one of silicon carbonic hydroxide, tetraethyl orthosilicate, undoped silicate glass, and boron phosphorus silicate glass.

3. The method as claimed in claim 1, further comprising forming an anti-oxidation layer on the gate conductive pattern before forming the interlayer insulating layer.

4. The method as claimed in claim 3, wherein forming the anti-oxidation layer includes:
depositing the anti-oxidation layer on the substrate, the gate insulating layer, and the gate conductive pattern, the anti-oxidation layer including a silicon nitride layer or a silicon oxynitride layer, and
removing portions of the anti-oxidation layer from the substrate.

5. The method as claimed in claim 1, wherein forming the gate buried trench includes:
forming a trench mask on the substrate to partially expose the active region and the isolation region, and
using the trench mask as an etch mask while partially removing the exposed active region and isolation region.

6. The method as claimed in claim 5, wherein forming the trench mask includes forming a pad oxide pattern and a mask pattern using a photolithography process to partially expose the active region and the isolation region.

7. The method as claimed in claim 6, further comprising removing the mask pattern before forming the interlayer insulating layer.

8. The method as claimed in claim 1, wherein forming the preliminary bit contact plug includes:
forming a plug mask on the interlayer insulating layer,
partially removing the interlayer insulating layer using the plug mask as an etch mask to form a bit contact hole partially exposing the active region, and
forming the bit contact plug in the bit contact hole.

9. The method as claimed in claim 1, further comprising:
sequentially forming a bit conductive layer and a hard mask layer on the bit contact plug, the bit conductive layer including a lower metal silicide layer, a barrier layer, an upper metal silicide layer, and an electrode layer;
partially removing the hard mask layer to form a hard mask pattern; and
performing a patterning process using the hard mask pattern as an etch mask to form a bit contact plug and a bit conductive pattern on the active region, the bit conductive pattern including a bit lower metal silicide pattern, a bit barrier pattern, a bit upper metal silicide pattern, and a bit electrode pattern.

10. The method as claimed in claim 9, wherein:
the substrate includes a cell area and a peripheral area,
the lower metal silicide layer, the barrier layer, the upper metal silicide layer, and the electrode layer are formed in both the cell area and the peripheral area, and
the bit lower metal silicide pattern, the bit barrier pattern, the bit upper metal silicide pattern, and the bit electrode pattern of the cell area are formed at substantially the same levels as the bit lower metal silicide pattern, the bit barrier pattern, the bit upper metal silicide pattern, and the bit electrode pattern of the peripheral area.

11. A method of fabricating a semiconductor device, the method comprising:
forming an isolation region in a substrate to define an active region;
forming a trench mask on the substrate to partially expose the active region and the isolation region;
partially removing the active region and the isolation region using the trench mask as an etch mask to form a gate buried trench;
forming a gate insulating layer on an inner wall of the gate buried trench;
forming a gate conductive pattern on the gate insulating layer to partially fill the gate buried trench;
forming an anti-oxidation layer on the gate conductive pattern;
forming a capping insulating layer on the anti-oxidation layer; and
forming an interlayer insulating layer on the substrate.

12. The method as claimed in claim 11, wherein the capping insulating layer and the interlayer insulating layer are formed of a same material, and the capping insulating layer and the interlayer insulating layer include a silicon oxide layer or a silicon oxynitride layer.

13. The method as claimed in claim 11, wherein forming the anti-oxidation layer includes forming a silicon nitride layer on the gate conductive pattern, the gate insulating layer, and the trench mask.

14. The method as claimed in claim 11, wherein forming the capping insulating layer includes:
forming a capping insulating material on the trench mask to fill the gate buried trench, and
removing portions of the capping insulating material so that the capping insulating material remains within the gate buried trench.

15. The method as claimed in claim 11, wherein, during the removal of portions of the capping insulating material, portions of the anti-oxidation layer and the trench mask are removed from the substrate.

16. A method of fabricating a semiconductor device, the method comprising:
forming an isolation region in a substrate to define an active region;
partially removing the active region and the isolation region to form a gate buried trench at a boundary between the active region and the isolation region;
forming a gate insulating layer on an inner wall of the gate buried trench;
forming a gate conductive pattern on the gate insulating layer to partially fill the gate buried trench;
forming an anti-oxidation layer on the gate conductive pattern, the anti-oxidation layer including a silicon nitride layer or a silicon oxynitride layer;
forming at least one insulating layer on the anti-oxidation layer, the at least one insulating layer being on the anti-oxidation layer within the gate buried trench and being on an uppermost surface of the substrate, and the at least one insulating layer including a silicon oxide layer; and
forming a bit conductive pattern on the at least one insulating layer.

17. The method as claimed in claim 16, wherein the at least one insulating layer includes a first insulating layer within the gate buried trench and a second insulating layer covering the uppermost surface of the substrate, both the first insulating layer and the second insulating layer being formed of a same material.

18. The method as claimed in claim 17, wherein the first insulating layer and the second insulating layer are formed as one single continuous layer after forming the anti-oxidation layer.

19. The method as claimed in claim 16, wherein the gate conductive pattern is formed spaced apart from the at least one insulating layer, the anti-oxidation layer being between the gate conductive pattern and the at least one insulating layer.

20. The method as claimed in claim 16, wherein the gate insulating layer, the gate conductive pattern, the anti-oxidation layer, and the at least one insulating layer are sequentially formed to completely fill the gate buried trench.
